(19) United States
(12) Patent Application Publication
(10) Pub. No.: US 2025/0107408 A1
(43) Pub. Date: Mar. 27, 2025

(54) Display Substrate and Display Apparatus

(71) Applicant: BOE TECHNOLOGY GROUP CO., LTD., Chaoyang District, Beijing (CN)

(72) Inventor: Xiaojin Zhang, Beijing (CN)

(21) Appl. No.: 18/729,582

(22) PCT Filed: Sep. 13, 2022
(86) PCT No.: PCT/CN2022/118555

§ 371 Date: Jul. 17, 2024

(30) Foreign Application Priority Data
Jul. 8, 2022 (CN) 202210798416.7

(51) Int. Cl. H10K 59/80; H10K 50/15; H10K 50/16; H10K 50/17; H10K 50/18; H10K 59/32; H10K 101/00; H10K 102/00

(52) U.S. Cl. CPC H10K 59/876; H10K 50/156; H10K 50/166; H10K 50/171; H10K 50/181; H10K 59/32; H10K 2101/90; H10K 2102/351

(57) ABSTRACT

A display substrate includes a backplane, and an anode layer, a first auxiliary layer, a first light-emitting layer, a second auxiliary layer, a plurality of second light-emitting layers of at least two different colors, a third auxiliary layer and a cathode layer that are stacked on the backplane in sequence. Microcavities are formed between the anode layer and the cathode layer. The first auxiliary layer includes film layers stacked in sequence, a number of the film layers being a; an optical thickness of the a film layers is L₁, and L₁ satisfies

$${L}_{1} = {\sum }_{h = 1}^{a} {n}_{h} {r}_{h}$$

The second auxiliary layer includes b film layers stacked in sequence, an optical thickness of the b film layers is L₂, and L₂ satisfies

$${L}_{2} = {\sum }_{i = 1}^{{b}_{}} {n}_{i} {r}_{i}$$

The third auxiliary layer includes c film layers stacked in sequence, an optical thickness of the c film layers in L₃, and L₃ satisfies

$${L}_{3} = {\sum }_{j = 1}^{c} {n}_{j} {r}_{j}$$

L₁, L₂, and L₃ satisfy

$$0.7 \leq \frac{{L}_{2}}{{L}_{1} + {L}_{3}} \leq 1.3 , \vert {L}_{1} - {L}_{3} \vert \leq 30 nm$$

### CROSS-REFERENCE TO RELATED APPLICATIONS

This application is the United States national phase of International Patent Application No. PCT/CN2022/118555 filed Sep. 13, 2022, and claims priority to Chinese Patent Application No. 202210798416.7, filed Jul. 8, 2022, the disclosures of which are hereby incorporated by reference in their entireties.

### BACKGROUND OF THE INVENTION

### Field of the Invention

The present disclosure relates to the field of display technologies, and in particular, to display substrates and a display apparatus.

### Description of Related Art

An organic light-emitting diode (OLED) display apparatus is a display apparatus made of organic self-luminous diodes. The OLED display apparatus has excellent properties such as no need for a backlight source, high contrast, small thickness, wide viewing angle, fast response speed, applicability to a flexible panel, a wide temperature range for use, a simple structure and a simple process, and is widely used currently.

### SUMMARY OF THE INVENTION

The purpose of embodiments of the present disclosure is to provide display substrates and a display apparatus.

In an aspect, a display substrate is provided. The display substrate includes a backplane, and an anode layer, a first auxiliary layer, a first light-emitting layer, a second auxiliary layer, a plurality of second light-emitting layers of at least two different colors, a third auxiliary layer and a cathode layer that are stacked on the backplane in sequence. Microcavities are formed between the anode layer and the cathode layer. The first light-emitting layer is disposed between the first auxiliary layer and the second auxiliary layer. The plurality of second light-emitting layers are disposed between the second auxiliary layer and the third auxiliary layer. The first auxiliary layer includes film layers stacked in sequence, a number of the film layers being a; an optical thickness of the a film layers is L₁, and L₁ satisfies:

$${L}_{1} = {\sum }_{h = 1}^{a} {n}_{h} {r}_{h} ;$$

where a is a positive integer, nₕ is a refractive index of an h-th film layer in the a film layers, and rₕ is a thickness of the h-th film layer.

The second auxiliary layer includes b film layers stacked in sequence, an optical thickness of the b film layers is L₂, and L₂ satisfies:

$${L}_{2} = {\sum }_{i = 1}^{b} {n}_{i} {r}_{i} ;$$

where b is a positive integer, nᵢ is a refractive index of an i-th film layer in the b film layers, and rᵢ is a thickness of the i-th film layer.

The third auxiliary layer includes c film layers stacked in sequence, an optical thickness of the c film layers is L₃, and L₃ satisfies:

$${L}_{3} = {\sum }_{j = 1}^{c} {n}_{j} {r}_{j} ;$$

where c is a positive integer, nⱼ is a refractive index of a j-th film layer in the c film layers, and rⱼ is a thickness of the j-th film layer.

L₁, L₂ and L₃ satisfy a formula:

$$0.7 \leq \frac{{L}_{2}}{{L}_{1} + {L}_{3}} \leq 1.3 , \vert {L}_{1} - {L}_{3} \vert \leq 30 nm .$$

In some embodiments, the plurality of second light-emitting layers include a plurality of second blue light-emitting layers, a plurality of second red light-emitting layers and a plurality of second green light-emitting layers. A wavelength of light emitted by the first light-emitting layer is less than a wavelength of light emitted by second light-emitting layers of at least one color.

In some embodiments, the first light-emitting layer includes a first guest material, a second light-emitting layer in the second light-emitting layers of at least one color includes a second guest material. An emission spectrum of the first guest material at least partially overlaps with an absorption spectrum of the second guest material of the second light-emitting layers of at least one color.

In some embodiments, an overlapping range between the emission spectrum of the first guest material and the absorption spectrum of the second guest material is greater than or equal to 60% of a wavelength range of the emission spectrum of the first guest material.

In some embodiments, an overlapping range between the emission spectrum of the first guest material and the absorption spectrum of the second guest material is greater than or equal to 60% of a wavelength range of the absorption spectrum of the second guest material.

In some embodiments, a peak value of the emission spectrum of the first guest material is less than 600 nm.

In some embodiments, the first guest material includes at least one luminescent material. In a case where the first guest material includes two luminescent materials, a distance between peaks of emission spectrums of the two luminescent materials is less than or equal to 30 nm.

In some embodiments, a peak value of the emission spectrum of the first guest material is in a range of 465 nm to 475 nm, and a peak value of an absorption spectrum of a second guest material of the second green light-emitting layers is in a range of 507 nm to 517 nm.

In some embodiments, a peak value of the emission spectrum of the first guest material is in a range of 525 nm to 535 nm, a peak value of an absorption spectrum of a second guest material of the second green light-emitting layers is in a range of 510 nm to 520 nm, and a peak value of an absorption spectrum of a second guest material of the second red light-emitting layers is in a range of 595 nm to 605 nm.

In some embodiments, the first guest material includes at least one luminescent material. In a case where the first guest material includes two luminescent materials, at least one of the two luminescent materials is doped with boron element, and a doping ratio of the boron element is in a range of 0.5% to 5%.

In some embodiments, the second guest material of the second light-emitting layers of at least one color includes at least one luminescent material. In a case where the second guest material includes two luminescent materials, a distance between peaks of emission spectrums of the two luminescent materials is less than or equal to 30 nm.

In some embodiments, the second guest material of the second light-emitting layers of at least one color includes at least one luminescent material. In a case where the second guest material includes two luminescent materials, at least one of the two luminescent materials is doped with boron element, and a doping ratio of the boron element is in a range of 0.5% to 5%.

In some embodiments, the first guest material includes at least one material of fluorescent materials, phosphorescent materials and a thermally activated delayed fluorescence material; and/or the second guest material includes at least one material of fluorescent materials, phosphorescent materials, or a thermally activated delayed fluorescence material with a multiple resonance property.

In some embodiments, the first light-emitting layer further includes a first host material, and the first host material includes a single host material or a PN hybrid host material.

In some embodiments, a material of the second light-emitting layers of at least one color further includes a second host material, and the second host material includes a bipolar host material.

In some embodiments, the second host material includes a single host material or a PN hybrid host material. In a case where the second host material is the PN hybrid host material, an N-type material in the PN hybrid host material has a thermally activated delayed fluorescence property.

In some embodiments, a microcavity in the microcavities includes a plurality of sub-microcavities, and the plurality of sub-microcavities include a red sub-microcavity corresponding to a second red light-emitting layer in the plurality of second red light-emitting layers, a green sub-microcavity corresponding to a second green light-emitting layer in the plurality of second green light-emitting layers, and a blue sub-microcavity corresponding to a second blue light-emitting layer in the plurality of second blue light-emitting layers. A number of film layers that are located between the anode layer and the cathode layer and correspond to a sub-microcavity of any color is d; and an optical thickness of the d film layers is L, and L satisfies:

$$L = {\sum }_{m = 1}^{d} {n}_{m} {r}_{m} , 2 L + \frac{φ}{2 π} = k λ ;$$

where d is a positive integer, nm is a refractive index of an m-th film layer in the d film layers, rₘ is a thickness of the m-th film layer, k is a natural number, λ is a peak wavelength of a target spectrum, and φ is a phase shift caused after target light is reflected by the anode layer.

In some embodiments, a length of the blue sub-microcavity is less than a length of the red sub-microcavity; and the length of the blue sub-microcavity is less than a length of the green sub-microcavity.

In some embodiments, a thickness of the first light-emitting layer is in a range of 15 nm to 60 nm; and/or a thickness of a second light-emitting layer in the plurality of second light-emitting layers of at least two different colors is in a range of 10 nm to 50 nm.

In some embodiments, the first auxiliary layer includes a light-transmitting conductive layer, a hole injection layer, a first hole transport layer and an electron blocking layer; and/or the second auxiliary layer includes a first hole blocking layer, a first electron transport layer, a first charge generation layer, a second charge generation layer and a microcavity adjustment layer; and/or the third auxiliary layer includes a second hole blocking layer, a second electron transport layer and an electron injection layer.

In some embodiments, the microcavity adjustment layer includes: a second hole transport layer; a red sub-microcavity adjustment layer disposed between the second hole transport layer and a second red light-emitting layer in the plurality of second red light-emitting layers; a green sub-microcavity adjustment layer disposed between the second hole transport layer and a second green light-emitting layer in the plurality of second green light-emitting layers; and a blue sub-microcavity adjustment layer disposed between the second hole transport layer and a second blue light-emitting layer in the plurality of second blue light-emitting layers. Lengths of the red sub-microcavity adjustment layer and the blue sub-microcavity adjustment layer are different, and lengths of the green sub-microcavity adjustment layer and the blue sub-microcavity adjustment layer are different.

In some embodiments, the red sub-microcavity adjustment layer includes a red hole transport layer and a red electron blocking layer that are stacked in sequence in a direction away from the backplane; and the green sub-microcavity adjustment layer includes a green hole transport layer and a green electron blocking layer that are stacked in sequence in the direction away from the backplane. The red hole transport layer and the green hole transport layer are used to adjust lengths of respective color sub-microcavities.

In some embodiments, a thickness of the light-transmitting conductive layer is less than or equal to 10 nm; and/or a thickness of the hole injection layer is less than or equal to 10 nm; and/or a thickness of the electron blocking layer is less than or equal to 10 nm; and/or a thickness of the first hole blocking layer is less than or equal to 10 nm; and/or a thickness of the first electron transport layer is in a range of 15 nm to 50 nm; and/or a thickness of the first charge generation layer is less than or equal to 10 nm; and/or a thickness of the second charge generation layer is less than or equal to 10 nm; and/or a thickness of the second hole blocking layer is less than or equal to 10 nm; and/or a thickness of the second electron transport layer is in a range of 15 nm to 50 nm.

In some embodiments, there are a plurality of first light-emitting layers, and a second auxiliary layer is disposed between any two adjacent first light-emitting layers; and/or second light-emitting layers in the plurality of second light-emitting layers of at least two different colors are located in a same layer and constitute a light-emitting layer group, and there are a plurality of light-emitting layer groups; and a third auxiliary layer is disposed between any two adjacent light-emitting layer groups.

In another aspect, a display substrate is provided. The display substrate includes a backplane, and an anode layer, a first auxiliary layer, a first light-emitting layer, a second auxiliary layer, a plurality of second light-emitting layers of at least two different colors, a third auxiliary layer and a cathode layer that are stacked on the backplane in sequence. Microcavities are formed between the anode layer and the cathode layer. The first light-emitting layer is disposed between the first auxiliary layer and the second auxiliary layer. The plurality of second light-emitting layers are disposed between the second auxiliary layer and the third auxiliary layer. The first auxiliary layer includes film layers stacked in sequence, a number of the film layers being a; the second auxiliary layer includes b film layers stacked in sequence; and the third auxiliary layer includes c film layers stacked in sequence; a, b, c are all positive integers. An optical thickness of the a film layers, an optical thickness of the b film layers and an optical thickness of the c film layers satisfy a formula:

$$0.7 \leq \frac{{\sum }_{i = 1}^{b} {r}_{i}}{{\sum }_{h = 1}^{a} {r}_{h} + {\sum }_{j = 1}^{c} {r}_{j}} \leq 1.3 , \vert \overline{n} {{\sum }_{h = 1}}^{a} {r}_{h} - \overline{n} {{\sum }_{j = 1}}^{c} {r}_{j} \vert \leq 30 nm ;$$

n̅ is an average refractive index of film layers between the anode layer and the cathode layer, and n is in a range of 1.7 to 2.0; rₕ is a thickness of an h-th film layer in the a film layers; rᵢ is a thickness of an i-th film layer in the b film layers; and rⱼ is a thickness of a j-th film layer in the c film layers.

In yet another aspect, a display substrate is provided. The display substrate includes a backplane, and an anode layer, a first auxiliary layer, a first light-emitting layer, a second auxiliary layer, a plurality of second light-emitting layers of at least two different colors, a third auxiliary layer and a cathode layer that are stacked on the backplane in sequence. The second auxiliary layer includes a charge generation layer, and microcavities are formed between the anode layer and the cathode layer. The first light-emitting layer is capable of emitting light of at least two different colors. The plurality of second light-emitting layers includes a plurality of second blue light-emitting layers, a plurality of second red light-emitting layers and a plurality of second green light-emitting layers. The first auxiliary layer includes film layers stacked in sequence, a number of the film layers being a; the second auxiliary layer includes b film layers stacked in sequence; and the third auxiliary layer includes c film layers stacked in sequence; a, b, c are all positive integers. An optical thickness of the a film layers, an optical thickness of the b film layers and an optical thickness of the c film layers satisfy a formula:

$$0.7 \leq \frac{{\sum }_{i = 1}^{b}}{{\sum }_{h = 1}^{a} {r}_{h} + {\sum }_{j = 1}^{c} {r}_{j}} \leq 1.3 , \vert \overline{n} {{\sum }_{h = 1}}^{a} {r}_{h} - \overline{n} {{\sum }_{j = 1}}^{c} {r}_{j} \vert \leq 30 nm .$$

n̅ is an average refractive index of film layers between the anode layer and the cathode layer, and n is in a range of 1.7 to 2.0; rₕ is a thickness of an h-th film layer in the a film layers, rᵢ is a thickness of an i-th film layer in the b film layers, and rⱼ is a thickness of a j-th film layer in the c film layers.

In yet another aspect, a display apparatus is provided. The display apparatus includes the display substrate as described in any one of the embodiments in the aspect; or the display apparatus includes the display substrate as described in the embodiments in the another aspect; or the display apparatus includes the display substrate as described in the embodiments in the yet another aspect.

The display apparatus has the same beneficial effects as the display substrates provided in the above some embodiments, which will not be repeated here.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display substrate, in accordance with some embodiments of the present disclosure;

FIG. 3 is a structural diagram of another display substrate, in accordance with some embodiments of the present disclosure;

FIG. 4 is a structural diagram of a display substrate in the first method;

FIG. 5 is a structural diagram of a display substrate in the second method;

FIG. 6 is a structural diagram of still another display substrate, in accordance with some embodiments of the present disclosure;

FIG. 7 is a structural diagram of still another display substrate, in accordance with some embodiments of the present disclosure;

FIG. 8 is a structural diagram of still another display substrate, in accordance with some embodiments of the present disclosure;

FIG. 9 is a structural diagram of still another display substrate, in accordance with some embodiments of the present disclosure;

FIG. 10 is a diagram showing spectrums of some of light-emitting layers in Verification Example 1;

FIG. 11 is a diagram showing spectrums of some of light-emitting layers in Verification Example 2;

FIG. 12 is a structural diagram of still another display substrate, in accordance with some embodiments of the present disclosure; and

FIG. 13 is a structural diagram of still another display substrate, in accordance with some embodiments of the present disclosure.

### DESCRIPTION OF THE INVENTION

The technical solutions in some embodiments of the present disclosure will be described clearly and completely in combination with the accompanying drawings; obviously, the described embodiments are merely some but not all embodiments of the present disclosure. All other embodiments obtained by a person of ordinary skill in the art based on embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the term “connected” and derivatives thereof may be used. For example, the term “connected” may be used in the description of some embodiments to indicate that two or more components are in direct physical or electrical contact with each other. The embodiments disclosed herein are not necessarily limited to the content herein.

The phrase “at least one of A, B, and C” has the same meaning as the phrase “at least one of A, B, or C,” and they both include the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The phrase “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term “about”, as used herein, includes a stated value and an average value within an acceptable range of deviation of a particular value determined by a person of ordinary skill in the art, considering measurement in question and errors associated with measurement of a particular quantity (i.e., limitations of a measurement system).

It should be understood that when a layer or element is referred to as being on another layer or substrate, the layer or element may be directly on another layer or substrate, or there may be intermediate layer(s) between the layer or element and the another layer or substrate.

Exemplary embodiments are described herein with reference to sectional views and/or plan views as idealized exemplary accompanying drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in apparatuses, and are not intended to limit the scope of the exemplary embodiments.

Some embodiments of the present disclosure provide a display substrate and a display apparatus. Hereinafter, the display substrate 100 and the display apparatus 1000 are introduced respectively in combination with the accompanying drawings.

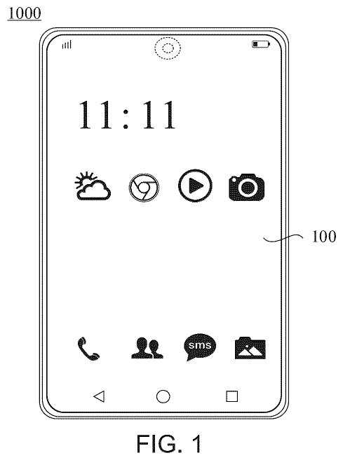

As shown in FIG. 1, some embodiments of the present disclosure provide a display apparatus 1000. The display apparatus 1000 may be any apparatus that displays images whether in motion (e.g., videos) or stationary (e.g., static images), and whether textual or graphical. More specifically, it is expected that the embodiments may be implemented in or associated with a variety of electronic apparatuses. The variety of electronic apparatuses may include (but are not limited to), for example, mobile phones, wireless apparatuses, personal data assistants (PDAs), hand-held or portable computers, GPS receivers/navigators, cameras, MP4 video players, video cameras, game consoles, watches, clocks, calculators, television monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), etc.

In some examples, the display apparatus 1000 includes a frame, and a display substrate 100, a circuit board, a data driver integrated circuit (IC) and other electronic accessories that are disposed in the frame.

The display substrate 100 may be, for example, an organic light-emitting diode (OLED) display substrate, a quantum dot light-emitting diode (QLED) display substrate, a micro light-emitting diode (Micro LED) display substrate or a mini light-emitting diode (Mini LED) display substrate, which is not specifically limited in the present disclosure.

Some embodiments of the present disclosure will be schematically described below by taking an example where the display substrate 100 is the OLED display substrate.

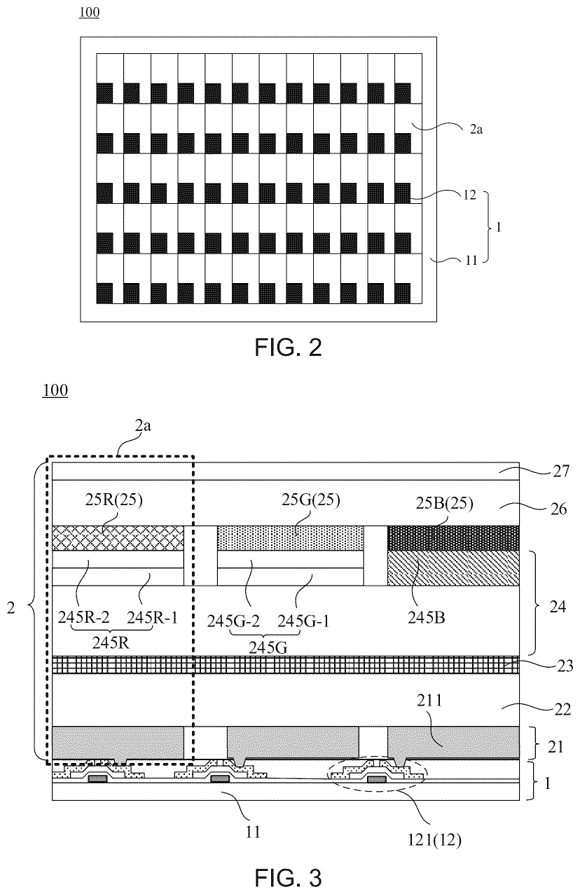

In some embodiments, as shown in FIG. 2, the display substrate 100 includes a backplane 1.

In some examples, the backplane 1 includes a substrate 11 and a plurality of pixel driving circuits 12 disposed on the substrate 11.

A type of the substrate 11 may vary, which may be set according to actual needs.

For example, the substrate 11 may be a rigid substrate. A material of the rigid substrate may include, for example, glass, quartz, or plastic.

For example, the substrate 11 may be a flexible substrate. A material of the flexible substrate may include, for example, polyethylene terephthalate (PET), polyethylene naphthalate two formic acid glycol ester (PEN) or polyimide (PI).

In some examples, the plurality of pixel driving circuits 12 are arranged in an array.

A structure of the pixel driving circuit 12 may vary, which may be set according to actual needs. For example, the pixel driving circuit 12 may be in a structure of “3T1C”, “4T1C”, “6T1C”, “7T1C”, “6T2C”, “7T2C” or “8T2C”. “T” represents a transistor, a number before “T” represents the number of transistors, “C” represents a storage capacitor, and a number before “C” represents the number of storage capacitors.

For example, the pixel driving circuit 12 is represented by one transistor 121 in FIG. 3.

In some embodiments, as shown in FIG. 3, the display substrate 100 further includes a light-emitting device layer 2.

In some examples, as shown in FIG. 3, the light-emitting device layer 2 includes a plurality of light-emitting devices 2a. As shown in FIG. 2, the plurality of light-emitting devices 2a are arranged in an array. The light-emitting device 2a is, for example, the OLED.

A pixel driving circuit 12 is electrically connected to a light-emitting device 2a.

Here, the electrical connection relationship between the two may vary, which may be selectively set according to actual needs, and the present disclosure does not limit this.

For example, the pixel driving circuits 12 and the light-emitting devices 2a can be electrically connected in a one-to-one correspondence. For another example, a single pixel driving circuit 12 can be electrically connected to multiple light-emitting devices 2a.

For example, multiple pixel driving circuits 12 can be electrically connected to a single light-emitting device 2a.

Hereinafter, a structure of the display substrate 100 will be schematically described by taking an example where the pixel driving circuits 12 and the light-emitting devices 2a can be electrically connected in a one-to-one correspondence.

It can be understood that the pixel driving circuit 12 can generate a driving signal and transmit the driving signal to the corresponding light-emitting device 2a, so as to control a light-emitting state of the light-emitting device 2a. The light-emitting state includes, for example, the light-emitting device 2a emitting light, the light-emitting device 2a not emitting light, or the brightness of the light-emitting device 2a. The plurality of the pixel driving circuits 12 together control light-emitting states of the plurality of light-emitting devices 2a, thereby enabling the display substrate 100 to display images.

Here, each pixel driving circuit 12 and a light-emitting device 2a electrically connected thereto may be referred as a sub-pixel.

It should be noted that there are two main ways for the display substrate to achieve full-color display. For example, one way is to provide a full-color display solution through individual light-emitting units R/G/B, and the other way is to provide a full-color display solution through color conversion or color filtering method.

In an implementation, providing the full-color display solution through individual light-emitting units R/G/B refers to that the light-emitting device mainly includes an anode, a light-emitting layer and a cathode that are stacked in sequence in a direction away from the substrate, and the light-emitting layer may be a red light-emitting layer, a green light-emitting layer or a blue light-emitting layer. Accordingly, the light-emitting device may be a red light-emitting device, a green light-emitting device or a blue light-emitting device.

The red light-emitting device is capable of emitting red light under control of a corresponding pixel driving circuit, the green light-emitting device is capable of emitting green light under control of a corresponding pixel driving circuit, and the blue light-emitting device is capable of emitting blue light under control of a corresponding pixel driving circuit. The plurality of the light-emitting devices cooperate with each other to achieve the full-color display. However, in this solution, the luminous efficiency and brightness of the light-emitting device are low.

In another implementation, there are two main ways to provide the full-color solution through the color conversion or color filtering method.

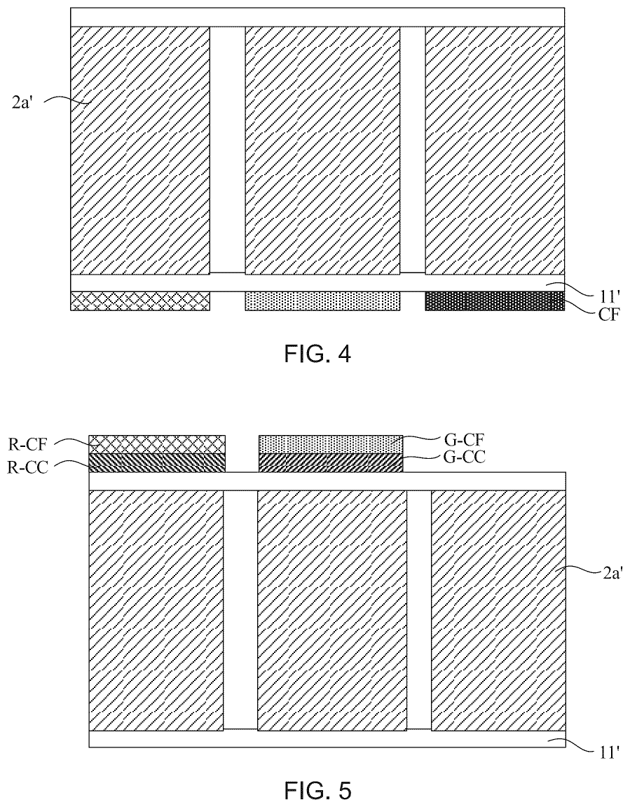

As shown in FIG. 4, in a first way, light-emitting devices 2a′ are bottom-emission light-emitting devices with a series structure, and the light-emitting devices are used to emit white light. The display substrate further includes color filters CF disposed on a side of the substrate 11′ away from the light-emitting devices 2a′. The white light emitted by the light-emitting device 2a′ is converted into red light, green light or blue light after passing through a color filter CF, thereby achieving the full-color display. However, due to the structure of the bottom-emission light-emitting device, it is difficult to improve the brightness under a front viewing angle. In addition, if top-emission light-emitting devices are used, there will be problems such as increased process complexity and excessive light loss in certain wave bands.

As shown in FIG. 5, in a second way, light-emitting devices 2a′ are top-emission light-emitting devices with a series structure, and the light-emitting devices 2a′ are used to emit blue light. The display substrate further includes red quantum dot conversion layers R-CC and green quantum dot conversion layers G-CC that are disposed on a side of the light-emitting devices 2a′ away from the substrate 11′. The blue light passing through the red quantum dot conversion layer R-CC can be converted into red light, and the blue light passing through the green quantum dot conversion layer G-CC can be converted into green light, thereby achieving the full-color display. However, due to the influence of light conversion rates of the red quantum dot conversion layer R-CC and the green quantum dot conversion layer G-CC themselves, the color purity of the converted red light and green light is low. Therefore, it is necessary to match corresponding filters. For example, a red filter R-CF needs to be provided on a side of the red quantum dot conversion layer R-CC away from the substrate 11′, and a green filter G-CF needs to be provided on a side of the green quantum dot conversion layer G-CC away from the substrate 11′, which facilitate to improve color purity. This will increase the process complexity of the display substrate and increase the power consumption of the display substrate.

Based on this, as shown in FIG. 3, in some embodiments of the present disclosure, the light-emitting device layer 2 includes an anode layer 21, a first auxiliary layer 22, a first light-emitting layer 23, a second auxiliary layer 24, a plurality of second light-emitting layers 25, a third auxiliary layer 26 and a cathode layer 27 that are disposed on the backplane 1.

In some examples, as shown in FIG. 3, the anode layer 21 includes a plurality of anodes 211, and the plurality of anodes 211 are arranged in an array. An anode 211 corresponds to a light-emitting device 2a. For example, each light-emitting device 2a is electrically connected to a corresponding pixel driving circuit 12 through the anode 211 thereof. The anode 211 can receive a driving signal of the corresponding pixel driving circuit 12 and cooperate with the corresponding pixel driving circuit 12, so as to achieve individual control of the light-emitting device 2a.

For example, a material of the anode layer 21 includes a conductive material with a relatively high work function. A structure of the anode layer 21 may be, for example, a single-layer structure, or a structure in which multiple film layers are stacked in sequence.

For example, in the case where the structure of the anode layer 21 is the single-layer structure, the single-layer structure has a relatively good light reflection performance and can reflect the light directed to the anode layer 21.

For example, in the case where the structure of the anode layer 21 is the structure in which multiple film layers are stacked in sequence, a film layer of the multiple film layers away from the backplane 1 is a film layer with a relatively good light reflection performance, which can reflect light directed to the anode layer 21. A material of the film layer with the relatively good light reflection performance may include, for example, at least one of Al (aluminum), Ag (silver) or Mg (magnesium). A film layer of the multiple film layers close to the backplane 1 may be, for example, a film layer with a relatively good light transmittance. A material of the film layer with the relatively good light transmittance may include, for example, ITO (indium tin oxide), IZO (indium zinc oxide), or the like.

For example, a method for forming the anodes 211 includes: forming a conductive film (the conductive film is of a single-layer structure or a structure in which multiple film layers are stacked in sequence, and is formed, for example, using a sputtering process) on the backplane 1, and then patterning the conductive film (e.g., etching the conductive film using a photolithography process) to obtain the plurality of anodes 211 that are independent of each other.

It should be noted that the display substrate 100 may further includes a pixel defining layer disposed on a side of the anode layer 21 away from the substrate 11. The pixel defining layer has a plurality of openings. The plurality of openings and the plurality of anodes 211 are arranged in a one-to-one correspondence. Each opening exposes a portion of a corresponding anode 211, which facilitates contact between the anode 211 and a film layer located on a side of the anode 211 away from the substrate 11 to form an electrical connection.

In some examples, as shown in FIG. 3, the first auxiliary layer 22 is disposed on the side of the anode layer 21 away from the substrate 11. Optionally, the first auxiliary layer 22 is located on a side of the pixel defining layer away from the substrate 11.

For example, the first auxiliary layer 22 may be in contact with the anode 211 through the opening of the pixel defining layer to form the electrical connection.

For example, the first auxiliary layer 22 includes film layers stacked in sequence, the number of the film layers being a, where a is a positive integer. For example, the number of the film layers included in the first auxiliary layer 22 is one, two, three or four.

Optionally, in the case where the first auxiliary layer 22 includes one film layer, the first auxiliary layer 22 covers the anode layer 21. That is, different light-emitting devices 2a share the first auxiliary layer 22.

Optionally, in the case where the first auxiliary layer 22 includes at least two film layers, at least one film layer in the at least two film layers covers the anode layer 21. That is, different light-emitting devices 2a share the at least one film layer.

For example, an evaporation process may be used to form the first auxiliary layer 22 in the embodiments of the present disclosure.

By making different light-emitting devices 2a share the film layer in the first auxiliary layer 22, it may be possible to avoid a patterning process for the first auxiliary layer 22, which is beneficial to simplifying the manufacturing process of the first auxiliary layer 22 and the display substrate 100.

In some examples, as shown in FIG. 3, the first light-emitting layer 23 is disposed on a side of the first auxiliary layer 22 away from the substrate 11.

For example, the first light-emitting layer 23 is arranged as a whole layer, and different light-emitting devices 2a share the first light-emitting layer 23.

It should be noted that, the first auxiliary layer 22 is located between the anode layer 21 and the first light-emitting layer 23, and the first auxiliary layer 22 is mainly used to increase hole mobility and lower injection barrier of holes, so as to increase an amount of holes that migrate to the first light-emitting layer 23, and to increase a recombination rate of holes and electrons that migrate to the first light-emitting layer 23, thereby improving the luminous efficiency of the first light-emitting layer 23.

In some examples, as shown in FIG. 3, the second auxiliary layer 24 is disposed on a side of the first light-emitting layer 23 away from the substrate 11. That is, the first light-emitting layer 23 is disposed between the first auxiliary layer 22 and the second auxiliary layer 24. The second auxiliary layer 24 is in contact with the first light-emitting layer 23 to form an electrical connection.

For example, the second auxiliary layer 24 includes b film layers stacked in sequence, where b is a positive integer. For example, the number of the film layers included in the second auxiliary layer 24 is one, two, three or four.

For example, different light-emitting devices 2a share the second auxiliary layer 24.

For example, an evaporation process may be used to form the second auxiliary layer 24 in the embodiments of the present disclosure.

By making different light-emitting devices 2a share the film layer in the second auxiliary layer 24, it may be possible to avoid a patterning process for the second auxiliary layer 24, which is beneficial to simplifying the manufacturing process of the second auxiliary layer 24 and the display substrate 100.

In some examples, as shown in FIG. 3, the plurality of second light-emitting layers 25 are disposed on a side of the second auxiliary layer 24 away from the substrate 11. For example, the plurality of second light-emitting layers 25 are located in the same layer, and each second light-emitting layer 25 is in contact with the second auxiliary layer 24 to form an electrical connection. Of course, at least two second light-emitting layers 25 in the plurality of second light-emitting layers 25 may also be stacked. The embodiments of the present disclosure are described by taking an example where the plurality of second light-emitting layers 25 are located in the same layer.

For example, the plurality of second light-emitting layers 25 have at least two different colors.

For example, the plurality of second light-emitting layers 25 have two different colors. Optionally, the plurality of second light-emitting layers 25 include a plurality of second blue light-emitting layers 25B and a plurality of second red light-emitting layers 25R; or the plurality of second light-emitting layers 25 include a plurality of second blue light-emitting layers 25B and a plurality of second green light-emitting layers 25G; or the plurality of second light-emitting layers 25 include a plurality of second red light-emitting layers 25R and a plurality of second green light-emitting layers 25G.

As another example, the plurality of second light-emitting layers 25 have three different colors. Optionally, the plurality of second light-emitting layers 25 include a plurality of second blue light-emitting layers 25B, a plurality of second red light-emitting layers 25R and a plurality of second green light-emitting layers 25G.

Since the plurality of second light-emitting layers 25 have at least two different colors, the plurality of second light-emitting layers 25 need to be formed in different processes, and second light-emitting layers 25 of a color may correspond to one process. For example, the second light-emitting layers 25 are formed using an evaporation process. In this case, the second light-emitting layers 25 of one color can be formed by evaporation in one process, and then the second light-emitting layers 25 of another color can be formed by evaporation in another process.

It should be noted that the second auxiliary layer 24 is located between the first light-emitting layer 23 and the plurality of second light-emitting layers 25. The second auxiliary layer 24 is mainly used to connect the first light-emitting layer 23 and the second light-emitting layers 25 in series to form the light-emitting devices with the series structure.

In some examples, as shown in FIG. 3, the third auxiliary layer 26 is disposed on a side of the plurality of second light-emitting layers 25 away from the substrate 11. That is, the plurality of second light-emitting layers 25 are disposed between the second auxiliary layer 24 and the third auxiliary layer 26. The third auxiliary layer 26 is in contact with each second light-emitting layer 25 to form an electrical connection.

For example, the third auxiliary layer 26 includes c film layers stacked in sequence, where c is a positive integer. For example, the number of the film layers included in the third auxiliary layer 26 is one, two or three.

Optionally, different light-emitting devices 2a share the third auxiliary layer 26.

For example, an evaporation process may be used to form the third auxiliary layer 26 in the embodiments of the present disclosure.

By making different light-emitting devices 2a share the third auxiliary layer 26, it may be possible to avoid a patterning process for the third auxiliary layer 26, which is beneficial to simplifying the manufacturing process of the third auxiliary layer 26 and the display substrate 100.

In some examples, as shown in FIG. 3, the cathode layer 27 is disposed on a side of the third auxiliary layer 26 away from the substrate 11, and is in contact with the third auxiliary layer 26 to form an electrical connection.

For example, different light-emitting devices 2a share the cathode layer 27. That is, the cathode layer 27 is of a whole-layer structure.

For example, an evaporation process may be used to form the cathode layer 27 in the embodiments of the present disclosure.

By making different light-emitting devices 2a share the cathode layer 27, it may be possible to avoid a patterning process for the cathode layer 27, which is beneficial to simplifying the manufacturing process of the cathode layer 27 and the display substrate 100.

It should be noted that, the third auxiliary layer 26 is located between the plurality of second light-emitting layers 25 and the cathode layer 27, and the third auxiliary layer 26 is mainly used to increase electron mobility, so as to increase an amount of electrons that migrate to the second light-emitting layers 25, to increase a recombination rate of holes and electrons that migrate to the second light-emitting layers 25, and to avoid leakage of holes or excitons formed by recombination of holes and electrons from the second light-emitting layers 25, thereby improving the luminous efficiency of the second light-emitting layers 25.

In some examples, the anode layer 21 has relatively high reflectivity, and the cathode layer 27 is a film layer with a transflective property. The term “transflective” means that the cathode layer 27 is capable of transmitting light and reflecting light, and the specific transmittance and reflectivity are not limited. This means that the light-emitting device 2a in the embodiments of the present disclosure is a top-emission light-emitting device.

For example, the reflectivity of the anode layer 21 is greater than or equal to 80%.

For example, a thickness of the cathode layer 27 is in a range of 10 nm to 20 nm. In this way, the light transmittance of the cathode layer 27 may be enhanced on the basis of ensuring the conductive performance of the cathode layer 27, and the luminous efficiency of the display substrate 100 may be improved.

For example, the thickness of the cathode layer 27 may be 10 nm, 12 nm, 14 nm, 17 nm or 20 nm.

For example, the transmittance of the cathode layer 27 for light with a wavelength of 530 nm is in a range of 45% to 60%.

For example, the transmittance may be 45%, 50%, 53%, 57% or 60%.

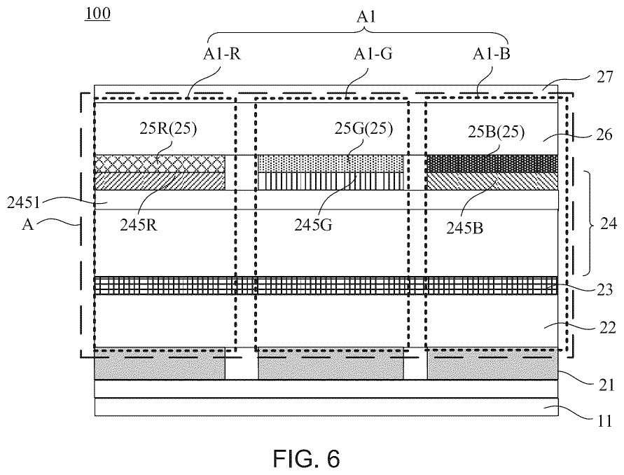

It can be understood that, as shown in FIG. 6, microcavities A can be formed between the anode layer 21 and the cathode layer 27 based on the properties of the anode layer 21 and the cathode layer 27. In this way, light emitted by the first light-emitting layer 23 and the second light-emitting layer 25 can be reflected and interfered within the microcavity A, which produces a microcavity effect, thereby enhancing the luminescent intensity of exit light, narrowing the spectrum of the exit light, and improving the luminous efficiency of the light-emitting device 2a. For example, the luminescent intensity of blue light may be enhanced and the spectrum of the blue light may be narrowed.

In some examples, an optical thickness of the film layers, the number of which is a, included in the first auxiliary layer 22 is L₁, and L₁ satisfies:

$${L}_{1} = {\sum }_{h = 1}^{a} {n}_{h} {r}_{h} ;$$

where nₕ is a refractive index of an h-th film layer in the a film layers, and rₕ is a thickness of the h-th film layer.

An optical thickness of the b film layers included in the second auxiliary layer 24 is L₂, and L₂ satisfies:

$${L}_{2} = {\sum }_{i = 1}^{b} {n}_{i} {r}_{i} ;$$

where nᵢ is a refractive index of an i-th film layer in the b film layers, and rᵢ is a thickness of the i-th film layer.

An optical thickness of the c film layers included in the third auxiliary layer 26 is L₃, and L₃ satisfies:

$${L}_{3} = {\sum }_{j = 1}^{c} {n}_{j} {r}_{j} .$$

nⱼ is a refractive index of a j-th film layer in the c film layers, and rⱼ is a thickness of the j-th film layer.

L₁, L₂ and L₃ satisfy the formula:

$$0.7 \leq \frac{{L}_{2}}{{L}_{1} + {L}_{3}} \leq 1.3 , \vert {L}_{1} - {L}_{3} \vert \leq 30 nm .$$

For example, a value of

$$\frac{{L}_{2}}{{L}_{1} + {L}_{3}}$$

may be 0.7, 0.83, 0.9, 1.1 or 1.3.

Through the above setting, the color purity of the light emitted by the light-emitting device 2a in the display substrate 100 may be improved. Therefore, provision of filters in the display substrate 100 in the embodiments of the present disclosure may be reduced, thereby reducing blocking of the light emitted by the light-emitting device 2a by the filter, and improving the luminous efficiency of the display substrate 100 in the embodiments of the present disclosure. Furthermore, the embodiments of the present disclosure may achieve the same brightness as the above-described first way and second way in a case of reducing a driving voltage of the pixel driving circuit 12 in the display substrate 100, thereby reducing the power consumption of the display substrate 100, and increasing the luminescent lifetime of the light-emitting device 2a.

It should be noted that refractive indexes of the h-th film layer, i-th film layer, and j-th film layer for light with a wavelength of 460 nm are all in a range of 1.7 to 2.0.

For example, the refractive indexes of the h-th film layer, i-th film layer, and j-th film layer for the light with the wavelength of 460 nm may be the same or different.

For example, the refractive indexes of the h-th film layer, i-th film layer, and j-th film layer for the light with the wavelength of 460 nm are 1.7, 1.75, 1.8, 1.9 or 2.0.

In some embodiments, as shown in FIG. 3, the plurality of second light-emitting layers 25 include a plurality of second blue light-emitting layers 25B, a plurality of second red light-emitting layers 25R and a plurality of second green light-emitting layers 25G. The wavelength of the light emitted by the first light-emitting layer 23 is less than that of the light emitted by the second light-emitting layers 25 of at least one color.

For example, the wavelength of the light emitted by the first light-emitting layer 23 is less than that of the light emitted by the second blue light-emitting layers 25B; or the wavelength of the light emitted by the first light-emitting layer 23 is less than that of the light emitted by the second red light-emitting layers 25R; or the wavelength of the light emitted by the first light-emitting layer 23 is less than that of the light emitted by the second green light-emitting layers 25G. Alternatively, the wavelength of the light emitted by the first light-emitting layer 23 is less than that of the light emitted by the second red light-emitting layers 25R, and is less than that of the light emitted by the second green light-emitting layers 25G, which is not limited in the present disclosure.

For example, the first light-emitting layer 23 is capable of emitting blue light or yellow light.

By making the wavelength of the light emitted by the first light-emitting layer 23 less than that of the light emitted by the second light-emitting layers 25 of at least one color, at least one of the second red light-emitting layer 25R, the second green light-emitting layer 25G and the second blue light-emitting layer 25B may be excited to emit light of a corresponding color in a case where the light emitted by the first light-emitting layer 23 is directed to the plurality of second light-emitting layers 25, thereby increasing the brightness and luminous efficiency of the display substrate 100. Moreover, as shown in FIG. 6, the light emitted by the first light-emitting layer 23 may also be reflected multiple times in the microcavity A, so that the light emitted by the first light-emitting layer 23 may be directed to the plurality of second light-emitting layers 25 multiple times, which further increases the excitation effect of the light emitted by the first light-emitting layer 23 on at least one of the plurality of second light-emitting layers 25, and in turn, increase the brightness and luminous efficiency of the display substrate 100.

It should be noted that, in the case where the plurality of second light-emitting layers 25 include the plurality of second blue light-emitting layers 25B, the plurality of second red light-emitting layers 25R and the plurality of second green light-emitting layers 25G, nₕ is the refractive index of the h-th film layer in the a film layers to the central wavelength of red light, green light or blue light, and nᵢ is the refractive index of the i-th film layer in the b film layers to the center wavelength of red light, green light or blue light.

For example, the wavelength of red light is in a range of 615 nm to 630 nm, the wavelength of green light is in a range of 515 nm to 535 nm, and the wavelength of blue light is in a range of 460 nm to 475 nm.

In some embodiments, the first light-emitting layer 23 includes a first guest material, the second light-emitting layer 25 includes a second guest material. An emission spectrum of the first guest material at least partially overlaps with an absorption spectrum of the second guest material of the second light-emitting layers 25 of at least one color.

It should be noted that materials of the first light-emitting layer 23 and the second light-emitting layer 25 each include a host material and a guest material doped in the host material. The host material itself has a good film-forming property and can be mixed with other materials with an excellent luminescent property. The guest material itself has the excellent luminescent property. Based on this, in the case where the first light-emitting layer 23 or the second light-emitting layer 25 is formed by using both the host material and the guest material doped therein, since the host material includes molecules in a high excitation energy state, and the molecules in the high excitation energy state can transfer their energy to the guest material, the wavelength of the light emitted by the first light-emitting layer 23 or the second light-emitting layer 25 can be changed, and the luminous efficiency of the first light-emitting layer 23 or the second light-emitting layer 25 can be improved.

For example, the first guest material is a material mainly used for emitting light in the first light-emitting layer 23, and the second guest material is a material mainly used for emitting light in the second light-emitting layer 25.

The above phrase “at least partially overlap” means that the emission spectrum of the first guest material partially overlaps with the absorption spectrum of the second guest material of the second light-emitting layers 25 of at least one color, or the emission spectrum of the first guest material all overlaps with the absorption spectrum of the second guest material of the second light-emitting layers 25 of at least one color.

For example, the emission spectrum of the first guest material of the first light-emitting layer 23 at least partially overlaps with the absorption spectrum of the second guest material of the second red light-emitting layers 25R; or the emission spectrum of the first guest material of the first light-emitting layer 23 at least partially overlaps with the absorption spectrum of the second guest material of the second green light-emitting layers 25G; or the emission spectrum of the first guest material of the first light-emitting layer 23 at least partially overlaps with the absorption spectrum of the second guest material of the second blue light-emitting layers 25B; or the emission spectrum of the first guest material of the first light-emitting layer 23 at least partially overlaps with not only the absorption spectrum of the second guest material of the second red light-emitting layers 25R, but also the absorption spectrum of the second guest material of the second green light-emitting layers 25G. The embodiments of the present disclosure are not limited these.

By at least partially overlapping the emission spectrum of the first guest material of the first light-emitting layer 23 with the absorption spectrum of the second guest material of the second light-emitting layers 25 of at least one color, a part of the light emitted by the first guest material of the first light-emitting layer 23 may be absorbed by the second guest material of the second light-emitting layers 25 of at least one color, so that the second guest material of the second light-emitting layers 25 of at least one color emits light under the excitation of the light emitted by the first guest material, thereby improving the luminous efficiency of the second guest material of the second light-emitting layer 25. Another part of the light emitted by the first guest material of the first light-emitting layer 23 may exit through the cathode layer 27 to form a series light-emitting device with the light emitted by the second light-emitting layer 25, enhancing the brightness of the display substrate 100.

It should be noted that, in a case where the light emitted by the first light-emitting layer 23 in the display substrate 100 is directed to the second light-emitting layer 25, the second light-emitting layer 25 can absorb the light emitted by the first light-emitting layer 23 and excite light of a corresponding color; and the first light-emitting layer 23 and the second light-emitting layer 25 themselves can also form series light-emitting components. Thus, the above two light-emitting mechanisms work together, and the display substrate 100 will obtain a higher luminous efficiency.

It can be understood that, the more the overlapping portion of the emission spectrum of the first guest material with the absorption spectrum of the second guest material of the second light-emitting layer 25, the more light emitted by the second guest material that is excited by the first guest material, the higher the luminous efficiency of the second guest material of the second light-emitting layer 25.

In some embodiments, the overlapping range between the emission spectrum of the first guest material of the first light-emitting layer 23 and the absorption spectrum of the second guest material of the second light-emitting layer 25 is greater than or equal to 60% of the wavelength range of the emission spectrum of the first guest material.

For example, the overlapping range between the emission spectrum of the first guest material and the absorption spectrum of the second guest material may be 60%, 70%, 80%, 90% or 99% of the wavelength range of the emission spectrum of the first guest material.

With this setting, greater than or equal to 60% of all light emitted by the first guest material may be absorbed by the second guest material, thereby improving the utilization rate of the light emitted by the first guest material by the second guest material.

In some embodiments, the overlapping range between the emission spectrum of the first guest material of the first light-emitting layer 23 and the absorption spectrum of the second guest material of the second light-emitting layer 25 is greater than or equal to 60% of the wavelength range of the absorption spectrum of the second guest material.

For example, the overlapping range between the emission spectrum of the first guest material and the absorption spectrum of the second guest material may be 60%, 70%, 80%, 90% or 99% of the wavelength range of the absorption spectrum of the second guest material.

With this setting, more of the light emitted by the first guest material may be absorbed by the second guest material, thereby improving the utilization rate of the light emitted by the first guest material by the second guest material.

In some embodiments, a peak value of the emission spectrum of the first guest material of the first light-emitting layer 23 is less than 600 nm.

For example, the peak value of the emission spectrum of the first guest material of the first light-emitting layer 23 may be 465 nm, 500 nm, 515 nm, 560 nm or 595 nm.

As mentioned above, the smaller the wavelength of light, the higher the energy the light has. Through the above setting, it may be ensured that the light emitted by the first light-emitting layer 23 has higher energy, so that the second guest material of the second light-emitting layer 25 may be better excited to emit light.

In some embodiments, the first guest material of first light-emitting layer 23 includes at least one luminescent material. In a case where the first guest material includes two luminescent materials, a distance between peaks of emission spectrums of the two luminescent materials is less than or equal to 30 nm.

For example, the first guest material may include one or two luminescent materials, which is not limited in the present disclosure.

It can be understood that different luminescent materials can emit light of different colors. In the case where the first guest material of the first light-emitting layer 23 includes one luminescent material, the first light-emitting layer 23 can emit light of one color; in the case where the first guest material of the first light-emitting layer 23 includes two luminescent materials, the first light-emitting layer 23 can emit light of two colors.

For example, in the case where the first guest material of the first light-emitting layer 23 includes two luminescent materials, the distance between the peaks of the emission spectrums of the two luminescent materials may be 1 nm, 10 nm, 19 nm, 25 nm or 30 nm.

By making the distance between the peaks of the emission spectrums of the two luminescent materials in the first guest material less than or equal to 30 nm, it may be possible to make the colors of light emitted by the two luminescent materials of the first guest material more similar, thereby improving the color purity of light emitted by the first light-emitting layer 23.

In some embodiments, the emission spectrum of the first guest material of the first light-emitting layer 23 overlaps with the absorption spectrum of the second guest material of the second green light-emitting layer 25G.

For example, the light emitted by the first guest material is blue light.

For example, the peak value of the emission spectrum of the first guest material is in a range of 465 nm to 475 nm, and the peak value of the absorption spectrum of the second guest material of the second green light-emitting layer 25G is in a range of 507 nm to 517 nm.

For example, the peak value of the emission spectrum of the first guest material may be 465 nm, 467 nm, 469 nm, 471 nm or 475 nm. The peak value of the absorption spectrum of the second guest material of the second green light-emitting layer 25G may be 507 nm, 509 nm, 512 nm, 514 nm or 517 nm.

With this setting, the emission spectrum of the first guest material may have a larger overlapping range with the absorption spectrum of the second guest material, thereby improving the luminous efficiency of the second guest material of the second light-emitting layer 25.

In some embodiments, the emission spectrum of the first guest material of the first light-emitting layer 23 overlaps with the absorption spectrums of second guest materials of second light-emitting layers 25 of two colors.

For example, the light emitted by the first guest material is green light.

For example, the peak value of the emission spectrum of the first guest material is in a range of 525 nm to 535 nm, the peak value of the absorption spectrum of the second guest material of the second green light-emitting layer 25G is in a range of 510 nm to 520 nm, and the peak value of the absorption spectrum of the second guest material of the second red light-emitting layer 25R is in a range of 595 nm to 605 nm.

For example, the peak value of the emission spectrum of the first guest material may be 525 nm, 527 nm, 529 nm, 531 nm or 535 nm. The peak value of the absorption spectrum of the second guest material of the second green light-emitting layer 25G may be 510 nm, 514 nm, 516 nm, 518 nm or 520 nm. The peak value of the absorption spectrum of the second guest material of the second red light-emitting layer 25R may be 595 nm, 597 nm, 600 nm, 602 nm or 605 nm.

With this setting, the emission spectrum of the first guest material of the first light-emitting layer 23 may have larger overlapping ranges with the absorption spectrums of the second guest materials of the second light-emitting layers 25 of two colors, thereby improving the luminous efficiency of the second guest materials of the second light-emitting layers 25.

In some embodiments, in the case where the first guest material of the first light-emitting layer 23 includes two luminescent materials, at least one of the two luminescent materials is doped with boron element, and a doping ratio of the boron element is in a range of 0.5% to 5%.

For example, the doping ratio of the boron element may be 0.5%, 1.5%, 3.5%, 4% or 5%.

In some embodiments, the first guest material of the first light-emitting layer 23 includes at least one material of fluorescent materials, phosphorescent materials, and a thermally activated delayed fluorescence material.

For example, the fluorescent materials include pyrene materials, fused-carbazole materials, and boron-containing materials. The phosphorescent materials include iridium (Ir) and platinum (Pt) complexes. The thermally activated delayed fluorescence material generally has a D-A structure, and a difference between S1 and T1 of the thermally activated delayed fluorescence material is less than 0.3 eV (i.e., S1−T1<0.3 eV), where S1 represents the energy level of the excited singlet state of the material, and T1 represents the energy level of the triplet electron excited state of the material.

In some embodiments, the first light-emitting layer 23 further includes a first host material. The first host material of the first light-emitting layer 23 is a single host material or a PN hybrid host material.

For example, the first host material includes at least one material of anthracene materials, fluorene materials, pyrene materials, and carbazole derivative materials. In some embodiments, a thickness of the first light-emitting layer 23 is in a range of 15 nm to 60 nm.

For example, the thickness of the first light-emitting layer 23 may be 15 nm, 20 nm, 35 nm, 45 nm or 60 nm.

In some embodiments, the second guest material of the second light-emitting layers 25 of at least one color includes at least one luminescent material. In a case where the second guest material includes two luminescent materials, a distance between peaks of emission spectrums of the two luminescent materials is less than or equal to 30 nm.

Optionally, the second red light-emitting layer may include at least one luminescent material, or the second green light-emitting layer may include at least one luminescent material, or the second blue light-emitting layer may include at least one luminescent material. Optionally, both the second red light-emitting layer and the second green light-emitting layer may include at least one luminescent material.

For example, the second guest material may include one or two luminescent materials, which is not limited in the present disclosure.

It can be understood that different luminescent materials can emit light of different colors. In the case where the second guest material of the second light-emitting layer 25 includes one luminescent material, the second light-emitting layer 25 can emit light of one color; in the case where the second guest material of the second light-emitting layer 25 includes two luminescent materials, the second light-emitting layer 25 can emit light of two colors.

For example, in the case where the second guest material of the second light-emitting layer 25 includes two luminescent materials, in the two luminescent materials, the emission spectrum of one luminescent material has an overlapping range with the absorption spectrum of the other luminescent material. This setting may increase the luminous efficiency of the two luminescent materials.

For example, in the case where the second guest material of the second light-emitting layer 25 includes two luminescent materials, the distance between the peaks of the emission spectrums of the two luminescent materials may be 1 nm, 10 nm, 19 nm, 25 nm or 30 nm.

By making the distance between the peaks of the emission spectrums of the two luminescent materials in the second guest material of the second light-emitting layer 25 less than or equal to 30 nm, it may be possible to make colors of the light emitted by the two luminescent materials of the second guest material more similar, thereby improving the color purity of the light emitted by the second light-emitting layer 25.

In some embodiments, in the case where the second guest material of the second light-emitting layers 25 of at least one color includes two luminescent materials, at least one of the two luminescent materials is doped with boron element, and a doping ratio of the boron element is in a range of 0.5% to 5%.

For example, the doping ratio of the boron element may be 0.5%, 1.5%, 3.5%, 4% or 5%.

In some embodiments, the second guest material includes at least one material of fluorescent materials, phosphorescent materials, and a thermally activated delayed fluorescence material with a multiple resonance (MR) property.

In some embodiments, the second light-emitting layers 25 of at least one color further include a second host material. The second host material includes a bipolar host material.

In some embodiments, the second host material is a single host material or a PN hybrid host material.

In some examples, in the case where the second host material is the PN hybrid host material, an N-type component of the PN hybrid host material has a thermally activated delayed fluorescence property.

It should be noted that, in the case where the N-type component has the thermally activated delayed fluorescence property, the luminous efficiency of the second guest material of the second light-emitting layer 25 may be improved.

In some embodiments, a thickness of the second light-emitting layer 25 is in a range of 10 nm to 50 nm.

For example, the thickness of the second light-emitting layer 25 may be 10 nm, 20 nm, 28 nm, 38 nm or 50 nm.

In some embodiments, as shown in FIG. 6, the microcavity A includes a plurality of sub-microcavities A1. The plurality of sub-microcavities A1 include a red sub-microcavity A1-R corresponding to the second red light-emitting layer 25R, a green sub-microcavity A1-G corresponding to the second green light-emitting layer 25G, and a blue sub-microcavity A1-B corresponding to the second blue light-emitting layer 25B. The number of film layers that are located between the anode layer 21 and the cathode layer 27 and correspond to a sub-microcavity A1 of any color is d; an optical thickness of the d film layers is L, and L satisfies:

$$L = {\sum }_{m = 1}^{d} {n}_{m} {r}_{m} , 2 L + \frac{φ}{2 π} = k λ ;$$

where d is a positive integer, nm is a refractive index of an m-th film layer in the d film layers, rₘ is a thickness of the m-th film layer, k is a natural number, λ is a peak wavelength of a target spectrum, and φ is phase shift caused after target light is reflected by the anode layer 21.

It should be noted that in the case where the plurality of second light-emitting layers 25 include the plurality of second blue light-emitting layers 25B, the plurality of second red light-emitting layers 25R and the plurality of second green light-emitting layers 25G, nₘ is the refractive index of the m-th film layer in the d film layers to the central wavelength of red light, green light or blue light.

For example, in a case where blue light is required to interfere, λ is the wavelength of blue light; in a case where red light is required to interfere, λ is the wavelength of red light; and in a case where green light is required to interfere, λ is the wavelength of green light.

For example, in a case where L of the red sub-microcavity A1-R satisfies the above formula, the red light emitted by the second red light-emitting layer 25R can produce a microcavity effect in the red sub-microcavity A1-R, thereby increasing the brightness of the red light and increasing the color purity of the red light.

Similarly, the green light emitted by the second green light-emitting layer 25G and the blue light emitted by the second blue light-emitting layer 25B can also produce microcavity effects in respective sub-microcavities A1, thereby increasing the brightness of the green light and the blue light, and increasing the color purity of the green light and the blue light.

In some embodiments, a length of the blue sub-microcavity A1-B is less than that of the red sub-microcavity A1-R, and the length of the blue sub-microcavity A1-B is less than that of the green sub-microcavity A1-G.

For example, the wavelength of red light is in a range of 615 nm to 630 nm, the wavelength of green light is in a range of 515 nm to 535 nm, and the wavelength of blue light is in a range of 460 nm to 475 nm. Therefore, in a case where the red light, green light, and blue light can all produce microcavity effects, the length of the blue sub-microcavity A1-B is the smallest.

It should be noted that any one of the first auxiliary layer 22, the second auxiliary layer 24, and the third auxiliary layer 26 may include one film layer or a plurality of film layers that are stacked in sequence. In the case where any one of the first auxiliary layer 22, the second auxiliary layer 24, and the third auxiliary layer 26 includes the plurality of film layers, each film layer may have a different function, so that the first auxiliary layer 22, the second auxiliary layer 24, and the third auxiliary layer 26 may have multiple functions.

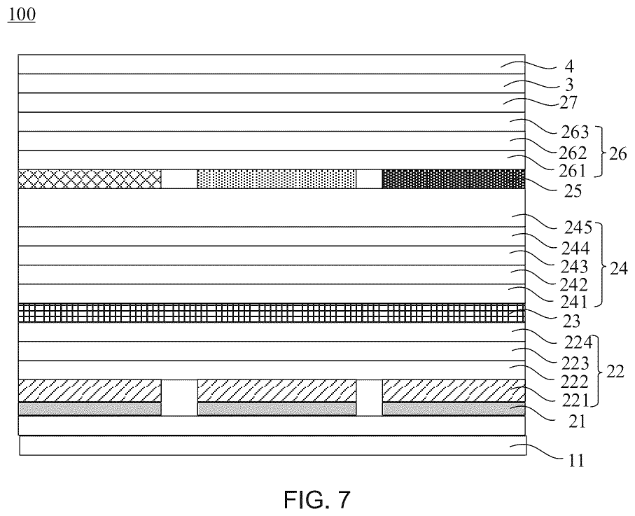

In some examples, as shown in FIG. 7, the first auxiliary layer 22 includes a light-transmitting conductive layer 221, a hole injection layer 222, a first hole transport layer 223 and an electron blocking layer 224.

The light-transmitting conductive layer 221 has good light-transmitting and conductivity. In a case where light is incident onto the light-transmitting conductive layer 221, the light can pass through the light-transmitting conductive layer 221 and direct towards the anode layer 21; the light reflection performance of the anode layer 21 is good, so that the light can be reflected on the anode layer 21 and the light-transmitting conductive layer 221.

For example, a material of the light-transmitting conductive layer 221 may include indium tin oxide (ITO), indium zinc oxide (IZO).

For example, a thickness of the light-transmitting conductive layer 221 is less than or equal to 10 nm. Optionally, the thickness of the light-transmitting conductive layer 221 is in a range of 5 nm to 10 nm.

For example, the thickness of the light-transmitting conductive layer 221 may be 5 nm, 6.5 nm, 8 nm, 9 nm or 10 nm.

For example, the hole injection layer 222 can be formed by doping a material of the first hole transport layer 223 with a P-type dopant (e.g., MnO₃ or F4TCNQ), and a doping ratio of the P-type dopant is less than or equal to 5%; a thickness of the hole injection layer 222 is less than or equal to 10 nm.

For example, the doping ratio of the P-type dopant in the material of the first hole transport layer 223 may be 1%, 2%, 3%, 4% or 5%. The thickness of the hole injection layer 222 may be 1 nm, 3 nm, 5 nm, 8 nm or 10 nm.

For example, the material of the first hole transport layer 223 includes a carbazole material with a relatively high hole mobility. The first hole transport layer 223 can be formed through an evaporation process.

For example, a thickness of the electron blocking layer 224 is less than or equal to 10 nm. For example, the thickness of the electron blocking layer 224 may be 1 nm, 3 nm, 5 nm, 8 nm or 10 nm.

For example, the highest occupied molecular orbital (HOMO) energy level of the material of the hole injection layer 222, the HOMO energy level of the material of the first hole transport layer 223, and the HOMO energy level of the material of the electron blocking layer 224 sequentially increase. This setting may lower injection barrier of holes and improve mobility of holes, which facilitates injection of holes from the anode layer 21 and subsequent transport of holes to the first light-emitting layer 23, thereby increasing an accumulated amount of holes in the first light-emitting layer 23, and improving the luminous efficiency and lifetime of the first light-emitting layer 23.

For example, the HOMO energy level of the material of the first hole transport layer 223 is in a range of −5.2 eV to −5.6 eV. For example, the HOMO energy level of the material of the first hole transport layer 223 may be −5.2 eV, −5.3 eV, −5.4 eV, −5.5 eV or −5.6 eV.

For example, the HOMO energy level of the material of the electron blocking layer 224 is in a range of −5.5 eV to −5.9 eV. For example, the HOMO energy level of the material of the electron blocking layer 224 is −5.5 eV, −5.6 eV, −5.7 eV, −5.8 eV, −5.9 eV.

For example, T1 of the material of the electron blocking layer 224 is greater than T1 of the luminescent material of the first light-emitting layer 23, which may prevent electrons and/or excitons from leaking from the first light-emitting layer 23, maintain the concentration of the electrons and/or excitons in the first light-emitting layer 23, and ensure the luminous efficiency of the first light-emitting layer 23.

For example, T1 of the material of the electron blocking layer 224 is at least 0.2 eV greater than T1 of the luminescent material of the first light-emitting layer 23.

In some examples, as shown in FIG. 7, the second auxiliary layer 24 includes a first hole blocking layer 241, a first electron transport layer 242, a first charge generation layer 243, a second charge generation layer 244 and a microcavity adjustment layer 245.

For example, an absolute value of the HOMO energy level of the material of the first hole blocking layer 241 is greater than that of the HOMO energy level of the material of the first light-emitting layer 23. The first hole blocking layer 241 is used to prevent holes and/or excitons from leaking from the first light-emitting layer 23.

For example, the absolute value of the HOMO energy level of the material of the first hole blocking layer 241 is at least 0.2 eV greater than the absolute value of the HOMO energy level of the material of the first light-emitting layer 23.

For example, T1 of the material of the first hole blocking layer 241 is greater than T1 of the luminescent material included in the first light-emitting layer 23.

For example, T1 of the material of the first hole blocking layer 241 is at least 0.2 eV greater than T1 of the luminescent material included in the first light-emitting layer 23.

For example, the material of the first hole blocking layer 241 includes a triazine material.

For example, a thickness of the first hole blocking layer 241 is less than or equal to 10 nm. For example, the thickness of the first hole blocking layer 241 is 1 nm, 3 nm, 5 nm, 8 nm or 10 nm.

For example, a material of the first electron transport layer 242 includes at least one material of thiophene materials, imidazole materials, azine derivative materials, and lithium quinolate. The first electron transport layer 242 can be manufactured by blending a thiophene, imidazole, or azine derivative material with lithium quinolate, in which the mass proportion of lithium quinolate is in a range of 30% to 70%.

For example, the mass proportion of lithium quinolate is 30%, 40%, 50%, 60% or 70%.

For example, a thickness of the first electron transport layer 242 is in a range of 15 nm to 50 nm. For example, the thickness of the first electron transport layer 242 is 15 nm, 23 nm, 35 nm, 40 nm or 50 nm.

For example, the first charge generation layer 243 and the second charge generation layer 244 are used to cause the first light-emitting layer 23 and the second light-emitting layer 25 in the light-emitting device layer 2 to emit light in series, thereby increasing the overall brightness of the display substrate 100.

For example, the first charge generation layer 243 can be formed by doping the material of the first electron transport layer 242 with a low-function metal (e.g., lithium (L₁), ytterbium (Yb), or calcium (Ca)), and a doping ratio of the low-function metal is less than or equal to 5%. A thickness of the first charge generation layer 243 is less than or equal to 10 nm.

For example, the doping ratio of the low-function metal may be 1%, 2%, 3%, 4% or 5%. The thickness of the first charge generation layer 243 may be 1 nm, 3 nm, 5 nm, 8 nm or 10 nm.

For example, the second charge generation layer 244 can be formed by doping a material of the second hole transport layer 2451 described below with a P-type dopant (e.g., MnO₃ or F4TCNQ), and a doping ratio of the P-type dopant is less than or equal to 5%. A thickness of the second charge generation layer 244 is less than or equal to 10 nm.

For example, the doping ratio of the P-type dopant may be 1%, 2%, 3%, 4% or 5%. The thickness of the second charge generation layer 244 may be 1 nm, 3 nm, 5 nm, 8 nm or 10 nm.

Optionally, the first charge generation layer 243 may also be called an N-type charge generation layer (N-CGL), and the second charge generation layer 244 may also be called a P-type charge generation layer (P-CGL).

For example, a thickness of the microcavity adjustment layer 245 is adjustable. By adjusting the thickness of the microcavity adjustment layer 245, the lengths of the plurality of sub-microcavities A1 may be adjusted, so that light corresponding to each sub-microcavity A1 may produce a microcavity effect.

In some embodiments, as shown in FIGS. 6 and 7, the microcavity adjustment layer 245 includes the second hole transport layer 2451, a red sub-microcavity adjustment layer 245R disposed between the second hole transport layer 2451 and the second red light-emitting layer 25R, a green sub-microcavity adjustment layer 245G disposed between the second hole transport layer 2451 and the second green light-emitting layer 25G, and a blue sub-microcavity adjustment layer 245B disposed between the second hole transport layer 2451 and the second blue light-emitting layer 25B. Thicknesses of the red sub-microcavity adjustment layer 245R and the blue sub-microcavity adjustment layer 245B are different, and thicknesses of the green sub-microcavity adjustment layer 245G and the blue sub-microcavity adjustment layer 245B are different.

For example, a material of the second hole transport layer 2451 includes a carbazole material with a relatively high hole mobility. The second hole transport layer 2451 can be formed through an evaporation process.

For example, the second hole transport layer 2451 is used to lower injection barrier of holes and increase mobility of holes, which facilitates transport of holes to the second light-emitting layer 25, thereby increasing an accumulated amount of holes in the second light-emitting layer 25, and improving the luminous efficiency and lifetime of the second light-emitting layer 25.

For example, the HOMO energy level of the material of the second hole transport layer 2451 is in a range of −5.2 eV to −5.6 eV. For example, the HOMO energy level of the material of the second hole transport layer 2451 is −5.2 eV, −5.3 eV, −5.4 eV, −5.5 eV, or −5.6 eV.

For example, T1 of a material of the red sub-microcavity adjustment layer 245R, T1 of a material of the green sub-microcavity adjustment layer 245G, and T1 of a material of the blue sub-microcavity adjustment layer 245B are greater than T1 of the luminescent material of the second light-emitting layer 25.

For example, T1 of the material of the red sub-microcavity adjustment layer 245R, T1 of the material of the green sub-microcavity adjustment layer 245G, and T1 of the material of the blue sub-microcavity adjustment layer 245B are at least 0.2 eV greater than T1 of the luminescent material of the second light-emitting layer 25.

For example, a thickness of the blue sub-microcavity adjustment layer 245B is less than or equal to 10 nm.

For example, the thickness of the blue sub-microcavity adjustment layer 245B may be 1 nm, 3 nm, 5 nm, 7 nm or 10 nm.

For example, thicknesses of the second hole transport layer 2451, the red sub-microcavity adjustment layer 245R, the green sub-microcavity adjustment layer 245G and the blue sub-microcavity adjustment layer 245B each are individually adjustable. By adjusting the thicknesses of the second hole transport layer 2451, the red sub-microcavity adjustment layer 245R, the green sub-microcavity adjustment layer 245G and the blue sub-microcavity adjustment layer 245B, the lengths of the plurality of sub-microcavities A1 may be adjusted, so that the light corresponding to each sub-microcavity A1 may produce the microcavity effect.

As mentioned above, the red light, green light, and blue light have different wavelengths. In a case where the red light, green light, and blue light can all produce microcavity effects, the lengths of the red sub-microcavity A1-R and the blue sub-microcavity A1-B are different, the lengths of the green sub-microcavity A1-G and the blue sub-microcavity A1-B are different. As shown in FIG. 6, the plurality of sub-microcavities A1 share the first auxiliary layer 22, the first light-emitting layer 23, a part of film layers in the second auxiliary layer 24 and the third auxiliary layer 26. By making the thicknesses of the red sub-microcavity adjustment layer 245R and the blue sub-microcavity adjustment layer 245B in the second auxiliary layer 24 different, and making the thicknesses of the green sub-microcavity adjustment layer 245G and the blue sub-microcavity adjustment layer 245B in the second auxiliary layer 24 are different, the plurality of sub-microcavities A1 may have required lengths by only adjusting the thicknesses of the red sub-microcavity adjustment layer 245R, the green sub-microcavity adjustment layer 245G and the blue sub-microcavity adjustment layer 245B, and the thickness of each of the shared film layers (such as the first auxiliary layer 22, the first light-emitting layer 23 and the third auxiliary layer 26) in the blue sub-microcavity A1-B, the red sub-microcavity A1-R and the green sub-microcavity A1-G is the same. Thus, the manufacturing process of the shared film layer may be simplified, and accordingly, the manufacturing process of the display substrate 100 may be simplified.

It should be noted that there is a small influence of the thicknesses of the second hole transport layer 2451, the red sub-microcavity adjustment layer 245R, the green sub-microcavity adjustment layer 245G and the blue sub-microcavity adjustment layer 245B on the electrical performance of the light-emitting device layer 2 in the display substrate 100. By adjusting the thicknesses of the second hole transport layer 2451, the red sub-microcavity adjustment layer 245R, the green sub-microcavity adjustment layer 245G and the blue sub-microcavity adjustment layer 245B, the lengths of the plurality of sub-microcavities A1 are adjusted, and the influence on the electrical performance of the light-emitting device layer 2 in the display substrate 100 may be reduced.

It can be understood that any one of the red sub-microcavity adjustment layer 245R, the green sub-microcavity adjustment layer 245G and the blue sub-microcavity adjustment layer 245B may include one film layer, or any one of the red sub-microcavity adjustment layer 245R, the green sub-microcavity adjustment layer 245G and the blue sub-microcavity adjustment layer 245B may include a plurality of film layers stacked in sequence.

In some embodiments, as shown in FIG. 3, the red sub-microcavity adjustment layer 245R includes a red hole transport layer 245R-1 and a red electron blocking layer 245R-2 that are stacked in sequence in the direction away from the backplane 1. The green sub-microcavity adjustment layer 245G includes a green hole transport layer 245G-1 and a green electron blocking layer 245G-2 that are stacked in sequence in the direction away from the backplane 1.

For example, the red hole transport layer 245R-1 can lower injection barrier of holes, which facilitates injection of holes from the second auxiliary layer 24 and transport of holes to the second red light-emitting layer 25G, thereby increasing an accumulated amount of holes in the second red light-emitting layer 25G, and improving the luminous efficiency and lifetime of the second red light-emitting layer 25G. The green hole transport layer 245G-1 can lower injection barrier of holes, which facilitates injection of holes from the second auxiliary layer 24 and transport of holes to the second green light-emitting layer 25G, thereby increasing an accumulated amount of holes in the second green light-emitting layer 25G, and improving the luminous efficiency and lifetime of the second green light-emitting layer 25G.

For example, the red electron blocking layer 245R-2 is used to block electrons and/or excitons from overflowing from the second red light-emitting layer 25G, and can confine the electrons and/or excitons in the second red light-emitting layer 25G, thereby improving the concentration of the electrons and/or excitons in the second red light-emitting layer 25G, and improving the brightness and luminous efficiency of the second red light-emitting layer 25G. The green electron blocking layer 245G-2 is used to block electrons and/or excitons from overflowing from the second green light-emitting layer 25G, and can confine the electrons and/or excitons in the second green light-emitting layer 25G, thereby improving the concentration of the electrons and/or excitons in the second green light-emitting layer 25G, and improving the brightness and luminous efficiency of the second green light-emitting layer 25G.

In some examples, the red hole transport layer 245R-1 and the green hole transport layer 245G-1 are used to adjust the lengths of respective sub-microcavities A1.

It can be understood that, in a case where thicknesses of other film layers (such as the first auxiliary layer 22 and the first light-emitting layer 23) remain unchanged, by changing the thicknesses of the red hole transport layer 245R-1 and the green hole transport layer 245G-1, the lengths of the corresponding red sub-microcavity A1-R and green sub-microcavity A1-G may be changed.

For example, by changing the thickness of the red hole transport layer 245R-1, the length of the red sub-microcavity A1-R can be changed. Thus, the red light may produce the microcavity effect in the red sub-microcavity A1-R, increasing the brightness and color purity of the red light. Furthermore, the wavelength of light that can produce the microcavity effect in the red sub-microcavity A1-R may also be changed, thereby adjusting the color of the light emitted by the red sub-microcavity A1-R. By changing the thickness of the green hole transport layer 245G-1, the length of the green sub-microcavity A1-G can be changed. Thus, the green light may produce the microcavity effect in the green sub-microcavity A1-G, increasing the brightness and color purity of the green light. Furthermore, the wavelength of light that can produce the microcavity effect in the green sub-microcavity A1-G may also be changed, thereby adjusting the color of the light emitted by the green sub-microcavity A1-G.

In some examples, as shown in FIG. 7, the third auxiliary layer 26 includes a second hole blocking layer 261, a second electron transport layer 262 and an electron injection layer 263.

For example, an absolute value of the HOMO energy level of the material of the second hole blocking layer 261 is greater than that of the HOMO energy level of the material of the second light-emitting layer 25. The second hole blocking layer 261 is used to prevent holes and/or excitons from leaking from the second light-emitting layer 25.

For example, the absolute value of the HOMO energy level of the material of the second hole blocking layer 261 is at least 0.2 eV greater than the absolute value of the HOMO energy level of the material of the second light-emitting layer 25.

For example, T1 of the material of the second hole blocking layer 261 is greater than T1 of the luminescent material included in the second light-emitting layer 25.

For example, T1 of the material of the second hole blocking layer 261 is at least 0.2 eV greater than T1 of the luminescent material included in the second light-emitting layer 25.

For example, the material of the second hole blocking layer 261 includes a triazine material.

For example, the thickness of the second hole blocking layer 261 is less than or equal to 10 nm. For example, the thickness of the second hole blocking layer 261 may be 1 nm, 3 nm, 5 nm, 8 nm or 10 nm.

For example, the material of the second electron transport layer 262 includes at least one material of thiophene materials, imidazole materials, azine derivative materials, and lithium quinolate. The second electron transport layer 262 can be manufactured by blending a thiophene, imidazole or azine derivative material with quinoline lithium, in which the mass proportion of quinoline lithium is in a range of 30% to 70%.

For example, the mass proportion of lithium quinolate may be 30%, 40%, 50%, 60% or 70%.

For example, the thickness of the second electron transport layer 262 is in a range of 15 nm to 50 nm. For example, the thickness of the second electron transport layer 262 may be 15 nm, 23 nm, 35 nm, 40 nm or 50 nm.

For example, the electron injection layer 263 is used to lower injection barrier of electrons, which facilitates injection of electrons from the cathode layer 27 and transport of electrons to the second light-emitting layer 25, thereby increasing an accumulated amount of electrons in the second light-emitting layer 25, and improving the luminous efficiency and lifetime of the second light-emitting layer 25.

For example, the material of the electron injection layer 263 includes lithium fluoride (LiF), ytterbium (Yb) or calcium (Ca). The electron injection layer 263 can be formed through an evaporation process.

For example, the thickness of the electron injection layer 263 is in a range of 0.5 nm to 2 nm. For example, the thickness of the electron injection layer 263 may be 0.5 nm, 0.8 nm, 1.2 nm, 1.7 nm or 2 nm.

In some examples, as shown in FIG. 7, the display substrate 100 further includes an optical covering layer 3 and/or an encapsulation layer 4 stacked in sequence on the cathode layer 27.

For example, a material of the optical covering layer 3 includes an organic material with a high refractive index. For example, the refractive index of the optical covering layer 3 for light with a wavelength of 530 nm is greater than 1.9.

For example, a thickness of the optical covering layer 3 is less than or equal to 100 nm. For example, the thickness of the optical covering layer 3 may be 10 nm, 30 nm, 50 nm, 80 nm or 100 nm.

For example, the encapsulation layer 4 can prevent film layers (such as the first light-emitting layer 23 and the second light-emitting layer 25) in the display substrate 100 from being in contact with water and oxygen in the air, so as to reduce the aging rate of the film layers and prolong service life of the display substrate 100.

For example, an encapsulation type of the encapsulation layer 4 includes sealant encapsulation or film encapsulation.

It should be noted that second light-emitting layers 25 are located in the same layer and constitute a light-emitting layer group. The present disclosure does not limit the number of first light-emitting layers 23 and the number of light-emitting layer groups. That is, the number of first light-emitting layers 23 may be one or more, and the number of light-emitting layer groups may be one or more.

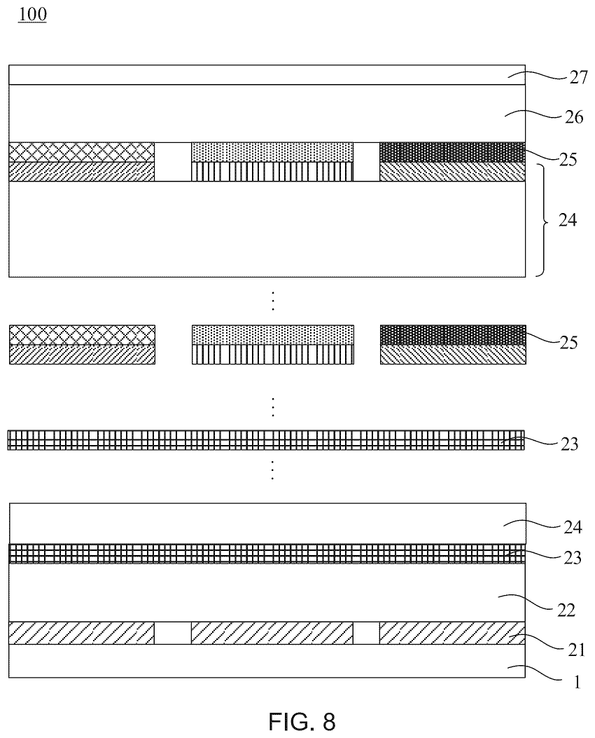

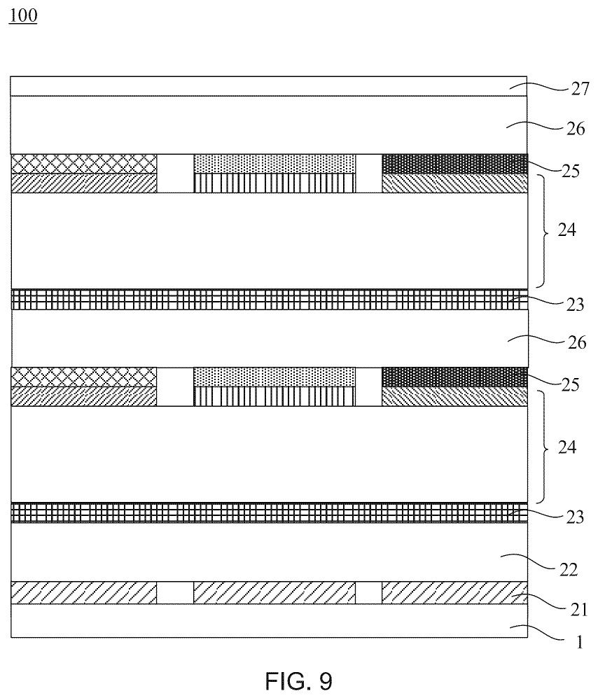

In some examples, as shown in FIG. 8, the number of first light-emitting layers 23 is multiple, and a second auxiliary layer 24 is disposed between any two adjacent first light-emitting layers 23; and/or, as shown in FIG. 9, the number of light-emitting layer groups is multiple, and a third auxiliary layer 26 is disposed between any two adjacent light-emitting layer groups.

For example, the number of first light-emitting layers 23 is two, three, four, five or six.

By arranging multiple first light-emitting layers 23, the total intensity of light emitted by the first light-emitting layers 23 may be increased, thereby increasing the intensity of excitation light of the second light-emitting layers 25, and increasing the brightness of the display substrate 100.

By arranging multiple light-emitting layer groups, the total intensity of light emitted by the light-emitting layer groups may be increased, thereby increasing absorption of light emitted by the first light-emitting layer 23 by the light-emitting layer groups, increasing the intensity of excitation light of the light-emitting layer groups, and increasing the brightness of the display substrate 100.

By arranging the second auxiliary layer 24 between any two adjacent first light-emitting layers 23 and arranging the third auxiliary layer 26 between any two adjacent light-emitting layer groups, it may be possible to ensure that holes and electrons can be transported to the first light-emitting layers 23 and the light-emitting layer groups to generate excitons, thereby causing the first light-emitting layers 23 and the light-emitting layer groups to emit light.

The inventor of the present disclosure has verified the color purity and luminous efficiency of the display substrate 100 disclosed herein.

Verification Example 1, which includes Comparison 1 and Embodiment 1.

A display substrate of Comparison 1 has red light-emitting devices, green light-emitting devices, and blue light-emitting devices, and another display substrate of Comparison 1 has first blue light-emitting devices. Both display substrates include an anode layer, a light-transmitting conductive layer, a hole injection layer, a hole transport layer, an electron blocking layer, light-emitting layers (e.g., including red light-emitting layers, green light-emitting layers, and blue light-emitting layers, or including blue light-emitting layers), a hole blocking layer, an electron transport layer, an electron injection layer, and a cathode layer that are stacked in sequence.

In Comparison 1, the red light-emitting layer in the red light-emitting device includes a red host material and a red phosphorescent luminescent material, and the mass proportion of the red phosphorescent luminescent material is 5%; the green light-emitting layer in the green light-emitting device includes a green host material and a green phosphorescent luminescent material with the multiple resonance property, and the mass proportion of the green phosphorescent luminescent material is 5%; the blue light-emitting layer in the blue light-emitting device includes a blue host material and a deep blue fluorescent material (the peak value of the emission spectrum is 460 nm), and the mass proportion of the deep blue fluorescent material is 5%. The blue light-emitting layer of the first blue light-emitting device includes an ordinary P-type blue host material, a blue luminescent material with the thermally activated delayed fluorescence property (the peak value of the emission spectrum is 500 nm), and a boron-containing blue fluorescent material with the multiple resonance property (the peak value of the emission spectrum is 470 nm), and the mass proportions of the three materials are 79%, 20%, and 1%, respectively.

The thickness of each film layer corresponding to the light-emitting device in each display substrate of Comparison 1 is shown in Table 1 below.

TABLE 1

| | Red light- | Green light- | Blue light- | First blue light- |
|---|---|---|---|---|
| Item | emitting device | emitting device | emitting device | emitting device |
| Thickness of anode layer (nm) | 100 | 100 | 100 | 100 |
| Thickness of light-transmitting conductive | 8 | 8 | 8 | 70 |
| layer (nm) | | | | |
| Thickness of hole injection layer (nm) | 10 | 10 | 10 | 10 |
| Thickness of hole transport layer (nm) | 15 | 15 | 15 | 100 |
| Thickness of electron blocking layer (nm) | 5 | 5 | 5 | 5 |
| Thickness of light-emitting layer (nm) | 25 | 30 | 20 | 30 |
| Thickness of hole blocking layer (nm) | 10 | 10 | 10 | 10 |
| Thickness of electron transport layer (nm) | 35 | 35 | 35 | 35 |
| Thickness of electron injection layer (nm) | 1 | 1 | 1 | 1 |
| Thickness of cathode layer (nm) | 15 | 15 | 15 | 100 |

A display substrate 100 of Embodiment 1 has red light-emitting devices, green light-emitting devices, and blue light-emitting devices. The display substrate 100 includes an anode layer, a light-transmitting conductive layer, a hole injection layer, a first hole transport layer, an electron blocking layer, a first light-emitting layer, a first hole blocking layer, a first electron transport layer, a first charge generation layer, a second charge generation layer, a second hole transport layer, a sub-microcavity adjustment layer of each color, a second light-emitting layer of each color, a second hole blocking layer, a second electron transport layer, an electron injection layer, and a cathode layer.

A material of the first light-emitting layer 23 In Embodiment 1 is the same as a material of the light-emitting layer of the first blue light-emitting device in Comparison 1, which includes the ordinary P-type blue host material, the blue luminescent material with the thermally activated delayed fluorescence property (the peak value of the emission spectrum is 500 nm), and the boron-containing blue fluorescent material with the multiple resonance property (the peak value of the emission spectrum is 470 nm), and the mass proportions of the three materials are 79%, 20%, and 1%, respectively.

And in Embodiment 1, the second light-emitting layer 25 in the red light-emitting device includes a red host material and a red phosphorescent luminescent material, and the mass proportion of the red phosphorescent luminescent material is 5%; the second light-emitting layer 25 in the green light-emitting device includes a green host material and a green phosphorescent luminescent material with the multiple resonance property, and the mass proportion of the green phosphorescent luminescent material is 5%; the second light-emitting layer 25 in the blue light-emitting device includes a blue host material and a deep blue fluorescent material (the peak value of the emission spectrum is 460 nm), and the mass proportion of the deep blue fluorescent material is 5%.

The thickness of each film layer corresponding to each light-emitting device in the display substrate 100 of Embodiment 1 is shown in Table 2 below.

TABLE 2

| | Red light- | Green light- | Blue light- |
|---|---|---|---|
| Item | emitting device | emitting device | emitting device |
| Thickness of anode layer (nm) | 100 | 100 | 100 |
| Thickness of light-transmitting | 8 | 8 | 8 |
| conductive layer (nm) | | | |
| Thickness of hole injection layer (nm) | 10 | 10 | 10 |
| Thickness of first hole transport layer (nm) | 25 | 25 | 25 |
| Thickness of electron blocking layer (nm) | 5 | 5 | 5 |
| Thickness of first light-emitting layer (nm) | 30 | 30 | 30 |
| Thickness of first hole blocking layer (nm) | 6 | 6 | 6 |
| Thickness of first electron transport layer (nm) | 10 | 10 | 10 |
| Thickness of first charge generation layer (nm) | 10 | 10 | 10 |
| Thickness of second charge generation layer (nm) | 10 | 10 | 10 |
| Thickness of second hole transport layer (nm) | 40 | 40 | 40 |
| Thickness of sub-microcavity adjustment layer of | 15 | 15 | 15 |
| each color (nm) | | | |
| Thickness of second light-emitting layer (nm) | 25 | 30 | 30 |
| Thickness of second hole blocking layer (nm) | 10 | 10 | 10 |
| Thickness of second electron transport layer (nm) | 35 | 35 | 35 |
| Thickness of electron injection layer (nm) | 1 | 1 | 1 |
| Thickness of cathode layer (nm) | 15 | 15 | 15 |
| Thickness of optical covering layer (nm) | 75 | 75 | 75 |

In Comparison 1 and Embodiment 1, a ratio of the P-type doping of the hole injection layer is 3%. A material of the cathode layer is magnesium-silver alloy, and a mass ratio of magnesium and silver in the magnesium-silver alloy is 1:9. A material of the electron transport layer is (8-hydroxyquinoline) lithium.

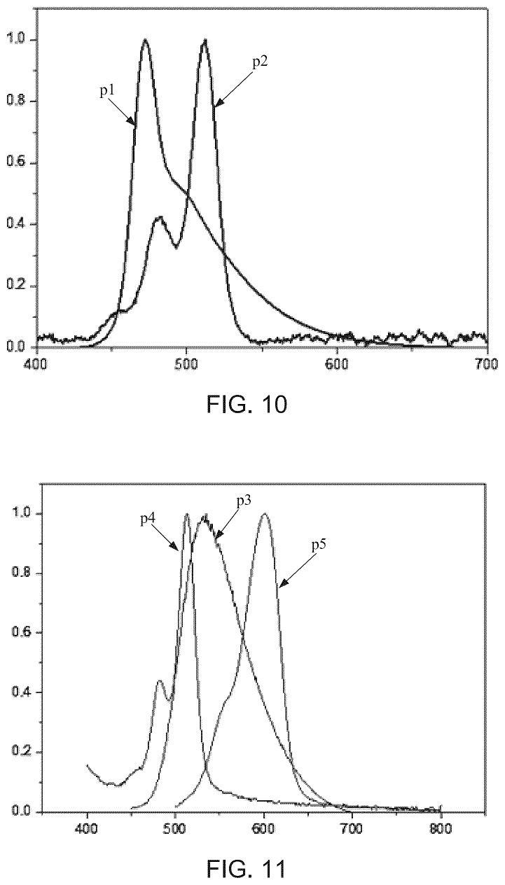

As shown in FIG. 10, the abscissa in the graph represents the wavelength in nm, and the ordinate in the graph represents the relative intensity of the spectrum. The light-emitting layer of the first blue light-emitting device of Comparison 1 and the first light-emitting layer 23 of the blue light-emitting device of Embodiment 1 both have the emission spectrum p1 with an obvious bimodal feature. The bimodal feature is caused by superposition of emission spectrums of the blue luminescent material with the thermally activated delayed fluorescence property (the peak value of the emission spectrum is 500 nm) and the boron-containing blue fluorescent material with the multiple resonance property (the peak value of the emission spectrum is 470 nm) in the material of the first light-emitting layer 23. In Embodiment 1, the absorption spectrum p2 of the red phosphorescent luminescent material of the second light-emitting layer 25 of the red light-emitting device overlaps with the emission spectrum p1 of the first light-emitting layer 23 of the blue light-emitting device. The relationship obtained by comparing relevant parameters of Comparison 1 and Embodiment 1 with those of the first blue light-emitting device is shown in Table 3.

The driving voltage of the first blue light-emitting device is 4.5 V, the brightness of the first blue light-emitting device is 1000, the chromatic coordinates of the first blue light-emitting device are (0.17, 0.32), and the luminous efficiency of the first blue light-emitting device is 38 cd/A.

TABLE 3

| | Color of light- | | Brightness | Chromatic | | |
|---|---|---|---|---|---|---|
| Item | emitting device | Voltage | (nits) | coordinates | Efficiency | LT95 lifetime |
| Comparison | Red | 100% | 5000 | 0.66, 0.34 | 100% | 100% |
| 1 | Green | 100% | 10000 | 0.25, 0.71 | 100% | 100% |
| | Blue | 100% | 1000 | 0.14, 0.045 | 100% | 100% |
| Embodiment | Red | 220% | 5000 | 0.67, 0.33 | 98% | 91% |
| 1 | Green | 210% | 10000 | 0.22, 0.75 | 620% | 1400% |
| | Blue | 220% | 1000 | 0.131, 0.056 | 287% | 470% |

It can be seen from the above results that, compared with Comparison 1, for the light-emitting device in Embodiment 1 in which the first light-emitting layer 23 and the second light-emitting layer 25 are combined in series, both the blue light-emitting device and the green light-emitting device exhibit several times increased efficiency and several times increased lifetime under the same brightness. The second light-emitting layer 25 of the red light-emitting device does not contain a luminescent material that can be excited by the light emitted by the first light-emitting layer 23, so that the second light-emitting layer 25 of the red light-emitting device maintains the original efficiency level. Moreover, due to microcavity adjustment, the color purity of the red light emitted by the red light-emitting layer in the red light-emitting device is also not affected. Although the lifetime of the red light-emitting layer is decreased, it still remains at a relatively high level.

Verification Example 2, which includes Comparison 2 and Embodiment 2.

A display substrate of Comparison 2 has red light-emitting devices, green light-emitting devices, and blue light-emitting devices, and another display substrate of Comparison 2 has first green light-emitting devices. Film layers included in each of the two display substrates are the same as the film layers included in the display substrate in Comparison 1.

In Comparison 2, the light-emitting layer in the red light-emitting device includes a P-type red host material, an N-type red host material with the thermally activated delayed fluorescence property, and a red fluorescent luminescent material, and the mass proportions of the above three materials are 69%, 30% and 1%, respectively; the light-emitting layer in the green light-emitting device includes a green host material and a green fluorescent luminescent material with the multiple resonance property, and the mass proportion of the green fluorescent luminescent material is 1%; and the light-emitting layer in the blue light-emitting device includes a blue host material and a deep blue fluorescent material (the peak value of the emission spectrum is 460 nm), and the mass proportion of the deep blue fluorescent material is 5%.

The thickness of each film layer corresponding to each light-emitting device in the display substrate of Comparison 2 is shown in Table 4 below.

TABLE 4

| | Red light- | Green light- | Blue light- | First blue light- |
|---|---|---|---|---|
| Item | emitting device | emitting device | emitting device | emitting device |
| Thickness of anode layer (nm) | 100 | 100 | 100 | 100 |
| Thickness of light-transmitting conductive | 8 | 8 | 8 | 70 |
| layer (nm) | | | | |
| Thickness of hole injection layer (nm) | 10 | 10 | 10 | 10 |
| Thickness of hole transport layer (nm) | 15 | 15 | 15 | 100 |
| Thickness of electron blocking layer (nm) | 5 | 5 | 5 | 5 |
| Thickness of single light-emitting layer | 25 | 30 | 20 | 30 |
| (nm) | | | | |
| Thickness of hole blocking layer (nm) | 10 | 10 | 10 | 10 |
| Thickness of electron transport layer (nm) | 35 | 35 | 35 | 35 |
| Thickness of electron injection layer (nm) | 1 | 1 | 1 | 1 |
| Thickness of cathode layer (nm) | 15 | 15 | 15 | 100 |

A structure of the display substrate 100 of Embodiment 2 is the same as that of the display substrate 100 of Embodiment 1.

A material of the first light-emitting layer 23 in Embodiment 2 is the same as that of the light-emitting layer of the first green light-emitting device in Comparison 2, and they both include an ordinary P-type green host material and a green luminescent material with the thermally activated delayed fluorescence property (the peak value of the emission spectrum is 460 nm), and the mass proportion of the green luminescent material with the thermally activated delayed fluorescence property is 30%.

In Embodiment 2, the second light-emitting layer 25 in the red light-emitting device includes a P-type red host material, an N-type red host material with the thermally activated delayed fluorescence property, and a red fluorescent luminescent material, and the mass proportions of the above three materials in the material of the second light-emitting layer 25 are 69%, 30%, and 1%, respectively; the second light-emitting layer 25 in the green light-emitting device includes a green host material and a green fluorescent luminescent material with the multiple resonance property, and the mass proportion of the green fluorescent luminescent material is 1%; the second light-emitting layer 25 in the blue light-emitting device includes a blue host material and a deep blue fluorescent material (the peak value of the emission spectrum is 460 nm), and the mass proportion of the deep blue fluorescent material in the material of the second light-emitting layer 25 is 5%.

The thickness of each film layer corresponding to each light-emitting device in the display substrate 100 of Embodiment 2 is shown in Table 5 below.

TABLE 5

| | Red light- | Green light- | Blue light- |
|---|---|---|---|
| Item | emitting device | emitting device | emitting device |
| Thickness of anode layer (nm) | 100 | 100 | 100 |
| Thickness of light-transmitting | 8 | 8 | 8 |
| conductive laver (nm) | | | |
| Thickness of hole injection layer (nm) | 10 | 10 | 10 |
| Thickness of first hole transport layer (nm) | 25 | 25 | 25 |
| Thickness of electron blocking layer (nm) | 5 | 5 | 5 |
| Thickness of first light-emitting layer (nm) | 30 | 30 | 30 |
| Thickness of first hole blocking layer (nm) | 8 | 8 | 8 |
| Thickness of first electron transport layer (nm) | 10 | 10 | 10 |
| Thickness of first charge generation layer (nm) | 8 | 8 | 8 |
| Thickness of second charge generation layer (nm) | 10 | 10 | 10 |
| Thickness of second hole transport layer (nm) | 40 | 40 | 40 |
| Thickness of sub-microcavity adjustment layer of | 15 | 15 | 15 |
| each color (nm) | | | |
| Thickness of second light-emitting layer (nm) | 20 | 20 | 20 |
| Thickness of second hole blocking layer (nm) | 10 | 10 | 10 |
| Thickness of second electron transport layer (nm) | 35 | 35 | 35 |
| Thickness of electron injection layer (nm) | 1 | 1 | 1 |
| Thickness of cathode layer (nm) | 15 | 15 | 15 |

The ratio of the P-type doping of the hole injection layer is 3%. The material of the cathode layer is magnesium-silver alloy, and the mass ratio of magnesium and silver in the magnesium-silver alloy is 1:9. The material of the electron transport layer is (8-hydroxyquinoline) lithium.

As shown in FIG. 11, the abscissa in the graph represents the wavelength in nm, and the ordinate in the graph represents the relative intensity of the spectrum. The first green light-emitting device in Comparison 2 and the first light-emitting layer 23 in Embodiment 2 both have the emission spectrum p3 with an obvious single-peak feature, and the emission spectrum p3 overlaps with the absorption spectrum p4 of the second light-emitting layer 25 of the red light-emitting device in Embodiment 2 and the absorption spectrum p5 of the second light-emitting layer 25 of the green light-emitting device in Embodiment 2. The relationship obtained by comparing relevant parameters of Comparison 2 and Embodiment 2 with those of the first green light-emitting device is shown in Table 6.

In Comparison 2, the driving voltage of the first green light-emitting device is 3.6 V, the brightness of the first green light-emitting device is 10000, the chromatic coordinates of the first green light-emitting device are (0.34, 0.60), and the luminous efficiency of the first green light-emitting device is 53 cd/A.

TABLE 6

| | Light-emitting | | Brightness | Chromatic | | |
|---|---|---|---|---|---|---|
| Item | device type | Voltage | (nits) | coordinates | Efficiency | LT95 lifetime |
| Comparison | Red | 100% | 5000 | 0.66, 0.34 | 100% | 100% |
| 2 | Green | 100% | 10000 | 0.21, 0.75 | 100% | 100% |
| | Blue | 100% | 1000 | 0.138, 0.042 | 100% | 100% |
| Embodiment | Red | 230% | 3000 | 0.67, 0.33 | 150% | 170% |
| 2 | Green | 228% | 10000 | 0.22, 0.75 | 450% | 820% |
| | Blue | 220% | 1000 | 0.132, 0.048 | 100% | 95% |

It can be seen from the above results that, compared with Comparison 2, for Embodiment 2 in which the first light-emitting layer 23 and the second light-emitting layer 25 are in series, both the red light-emitting device and the green light-emitting device exhibit higher efficiency and better lifetime level under the same brightness. The second light-emitting layer 25 of the blue light-emitting device cannot obtain additional gain from the first light-emitting layer 23, and thus, maintains similar efficiency and lifetime level to those of the blue light-emitting device in Comparison 2.

Verification Example 3, which includes Embodiment 3-1 and Embodiment 3-2.

Display substrates 100 of Embodiment 3-1 and Embodiment 3-2 both have red light-emitting devices, green light-emitting devices, and blue light-emitting devices. The display substrates 100 of Embodiment 3-1 and Embodiment 3-2 both include an anode layer, a light-transmitting conductive layer, a hole injection layer, a first hole transport layer, an electron blocking layer, a first light-emitting layer, a first hole blocking layer, a first electron transport layer, a first charge generation layer, a second charge generation layer, a second hole transport layer, a sub-microcavity adjustment layer of each color, a second light-emitting layer of each color, a second hole blocking layer, a second electron transport layer, an electron injection layer, a cathode layer, and an optical covering layer that are stacked in sequence.

The thickness of each film layer in the display substrate 100 of Embodiment 3-1 is shown in Table 7 below.

TABLE 7

| | Red light- | Green light- | Blue light- |
|---|---|---|---|
| Item | emitting device | emitting device | emitting device |
| Thickness of anode layer (nm) | 100 | 100 | 100 |
| Thickness of light-transmitting | 8 | 8 | 8 |
| conductive layer (nm) | | | |
| Thickness of hole injection layer (nm) | 10 | 10 | 10 |
| Thickness of first hole transport layer (nm) | 25 | 25 | 25 |
| Thickness of electron blocking layer (nm) | 5 | 5 | 5 |
| Thickness of first light-emitting layer (nm) | 30 | 30 | 30 |
| Thickness of first hole blocking layer (nm) | 6 | 6 | 6 |
| Thickness of first electron transport layer (nm) | 10 | 10 | 10 |
| Thickness of first charge generation layer (nm) | 10 | 10 | 10 |
| Thickness of second charge generation layer (nm) | 10 | 10 | 10 |
| Thickness of second hole transport layer (nm) | 39 | 39 | 39 |
| Thickness of sub-microcavity adjustment layer of | 15 | 15 | 15 |
| each color (nm) | | | |
| Thickness of second light-emitting layer (nm) | 25 | 30 | 20 |
| Thickness of second hole blocking layer (nm) | 10 | 10 | 10 |
| Thickness of second electron transport layer (nm) | 35 | 35 | 35 |
| Thickness of electron injection layer (nm) | 1 | 1 | 1 |
| Thickness of cathode layer (nm) | 15 | 15 | 15 |

The thickness of each film layer in the display substrate 100 of Embodiment 3-2 is shown in Table 8 below.

TABLE 8

| | Red light- | Green light- | Blue light- |
|---|---|---|---|
| Item | emitting device | emitting device | emitting device |
| Thickness of anode layer (nm) | 100 | 100 | 100 |
| Thickness of light-transmitting | 8 | 8 | 8 |
| conductive layer (nm) | | | |
| Thickness of hole injection layer (nm) | 10 | 10 | 10 |
| Thickness of first hole transport layer (nm) | 40 | 40 | 40 |
| Thickness of electron blocking layer (nm) | 5 | 5 | 5 |
| Thickness of first light-emitting layer (nm) | 30 | 30 | 30 |
| Thickness of first hole blocking layer (nm) | 6 | 6 | 6 |
| Thickness of first electron transport layer (nm) | 10 | 10 | 10 |
| Thickness of first charge generation layer (nm) | 8 | 8 | 8 |
| Thickness of second charge generation layer (nm) | 8 | 8 | 8 |
| Thickness of second hole transport layer (nm) | 24 | 24 | 24 |
| Thickness of sub-microcavity adjustment layer of | 10 | 10 | 10 |
| each color (nm) | | | |
| Thickness of second light-emitting layer (nm) | 25 | 30 | 20 |
| Thickness of second hole blocking layer (nm) | 10 | 10 | 10 |
| Thickness of second electron transport layer (nm) | 35 | 35 | 35 |
| Thickness of electron injection layer (nm) | 1 | 1 | 1 |
| Thickness of cathode layer (nm) | 15 | 15 | 15 |
| Thickness of optical covering layer (nm) | 75 | 75 | 75 |

The ratio of the P-type doping of the hole injection layer in Embodiment 3-1 and Embodiment 3-2 is 3%. The material of the cathode layer is magnesium-silver alloy, and the mass ratio of magnesium and silver in the magnesium-silver alloy is 1:9. The material of the electron transport layer is (8-hydroxyquinoline) lithium.

Relative to Embodiment 3-1, in Embodiment 3-2, by adjusting the thickness of the first hole transport layer close to the anode layer 21, the optical thickness L₁ can be adjusted; and at the same time, by adjusting the thickness of the second hole transport layer far away from the anode layer 21, the length of each sub-microcavity A1 is corrected. That is, the thickness of the first hole transport layer close to the anode layer 21 in Embodiment 3-2 is 15 nm (40 nm-25 nm=15 nm) greater than the thickness of the first hole transport layer close to the anode layer 21 in Embodiment 3-1, and the thickness of the second hole transport layer far away from the anode layer 21 in Embodiment 3-2 is 15 nm less than the thickness of the second hole transport layer far away from the anode layer 21 in Embodiment 3-1.

The results of the luminous purity and efficiency of Embodiment 3-1 relative to Embodiment 3-2 are shown in Table 9.

TABLE 9

| | Color of | | | | | | | |
|---|---|---|---|---|---|---|---|---|
| | light- | | | | | | | |
| | emitting | | Brightness | Chromatic | | | L₂/ | \|L1 − L3\| |
| Item | device | Voltage | (nits) | coordinates | Efficiency | Lifetime | (L₁ + L₃) | (k = 1) |
| Embodiment | Red | 100% | 5000 | 0.687, 0.313 | 100% | 100% | 0.9 | 14.8 nm |
| 3-1 | Green | 100% | 15000 | 0.275, 0.699 | 100% | 100% | | |
| | Blue | 100% | 1000 | 0.141, 0.045 | 100% | 100% | | |
| Embodiment | Red | 101% | 5000 | 0.688, 0.313 | 95% | 100% | 0.67 | 42.6 nm |
| 3-2 | Green | 100% | 15000 | 0.276, 0.698 | 96% | 100% | | |
| | Blue | 100% | 1000 | 0.135, 0.055 | 83% | 101% | | |

It can be seen from the above results that the blue light-emitting device in Embodiment 3-2 has low luminous efficiency and low color purity. The main reason is that there are significant deviations between L₁, L₂, L₃ corresponding to the blue light-emitting device and optimized sizes, and L₁, L₂, L₃ do not satisfy the formula:

$$0.7 \leq \frac{{L}_{2}}{{L}_{1} + {L}_{3}} \leq 1.3 , \vert {L}_{1} - {L}_{3} \vert \leq 30 nm .$$

This causes a long-wavelength mode component of the resonance in the blue sub-microcavity A1-B3 too high.

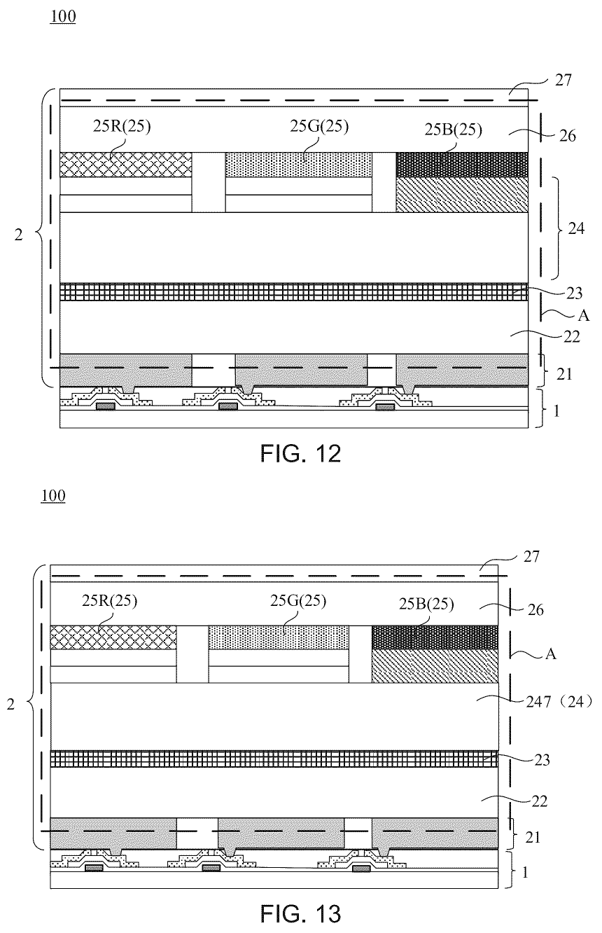

Some other embodiments of the present disclosure further provide a display substrate 100. As shown in FIG. 12, the display substrate 100 includes a backplane 1 and a light-emitting device layer 2.

In some examples, as shown in FIG. 12, the light-emitting device layer 2 includes an anode layer 21, a first auxiliary layer 22, a first light-emitting layer 23, a second auxiliary layer 24, a plurality of second light-emitting layers 25, a third auxiliary layer 26 and a cathode layer 27 that are disposed on the backplane 1. Microcavities A are formed between the anode layer 21 and the cathode layer 27.

In some examples, the plurality of second light-emitting layers 25 include a plurality of second blue light-emitting layers 25B, a plurality of second red light-emitting layers 25R, and a plurality of second green light-emitting layers 25G.

The first auxiliary layer includes film layers stacked in sequence, and the number of the film layers being a; the second auxiliary layer includes b film layers stacked in sequence; and the third auxiliary layer includes c film layers stacked in sequence. a, b, c are all positive integers.

The optical thickness of the a film layers, the optical thickness of the b film layers and the optical thickness of the c film layers satisfy the formula:

$$0.7 \leq \frac{{\sum }_{i = 1}^{b} {r}_{i}}{{\sum }_{h = 1}^{a} {r}_{h} + {\sum }_{j = 1}^{c} {r}_{j}} \leq 1.3 , \vert \overline{n} {\sum }_{h = 1}^{a} {r}_{h} - \overline{n} {\sum }_{j = 1}^{c} {r}_{j} \vert \leq 30 nm ;$$

n̅ is the average refractive index of the film layers between the anode layer 21 and the cathode layer 27, and n is in a range of 1.7 to 2.0; rₕ is the thickness of the h-th film layer in the a film layers; rᵢ is the thickness of the i-th film layer in the b film layers; and rⱼ is the thickness of the j-th film layer in the c film layers.

For example, a value of

$$\frac{{\sum }_{i = 1}^{b} {r}_{i}}{{\sum }_{h = 1}^{a} {r}_{h} + {\sum }_{j = 1}^{c} {r}_{j}}$$

may be, for example 0.7, 0.83, 0.9, 1.1 or 1.3.

It should be noted that the average refractive index is a sum of optical thicknesses of the film layers located between the anode layer 21 and the cathode layer 27 divided by a sum of actual thicknesses of the film layers located between the anode layer 21 and the cathode layer 27. Alternatively, the average refractive index of the film layers between the anode layer 21 and the cathode layer 27 can be directly measured by a refractive index testing device (e.g., a refractometer or an ellipsometer).

For example, the value of n may be, for example, 1.7, 1.75, 1.8, 1.9 or 2.0.

In some examples, in the display substrate 100 provided in the above embodiments, a difference between refractive indexes of any two of the film layers located between the anode layer 21 and the cathode layer 27 is less than or equal to 0.32. With this setting, the refractive indexes of any two of the film layers located between the anode layer 21 and the cathode layer 27 may be made relatively close, so that the difference between the refractive indexes of any two of the film layers located between the anode layer 21 and the cathode layer 27 is relatively small. Thus, the sudden change in the refractive index of each film layer may be reduced, which makes the light-emitting device 2a has good light extraction efficiency and reduces dispersion of the light emitted by the light-emitting device 2a.

It should be noted that the structure of the display substrate 100 in this embodiment is the same as that of the display substrate 100 in the above some embodiments. Optionally, the backplane 1 in this embodiment has the same features as the backplane 1 in the above some embodiments. The light-emitting device layer 2 in this embodiment has the same features as the light-emitting device layer 2 in the above some embodiments. For details, reference may be made to the above description, which will not be repeated here.

Some yet other embodiments of the present disclosure further provide a display substrate 100. As shown in FIG. 13, the display substrate 100 includes a backplane 1 and a light-emitting device layer 2.

In some examples, as shown in FIG. 13, the light-emitting device layer 2 includes an anode layer 21, a first auxiliary layer 22, a first light-emitting layer 23, a second auxiliary layer 24, a plurality of second light-emitting layers 25, a third auxiliary layer 26 and a cathode layer 27 that are disposed on the backplane 1. Microcavities A are formed between the anode layer 21 and the cathode layer 27.

In some examples, the second auxiliary layer 24 includes a charge generation layer 247.

For example, the charge generation layer 247 may include an N-type charge generation layer (N-CGL) and a P-type charge generation layer (P-CGL).

In some examples, the first light-emitting layer 23 is capable of emitting light of at least two different colors.

For example, the first light-emitting layer 23 can emit red light and blue light, or the first light-emitting layer 23 can emit green light and blue light, or the first light-emitting layer 23 can emit red light, green light and blue light.

Since the first light-emitting layer 23 has two different colors, the first light-emitting layer 23 needs to be formed in different processes, in which the first light-emitting layer 23 of a color can correspond to one process. For example, the first light-emitting layer 23 is formed by an evaporation process. In this case, the first light-emitting layer 23 of one color can be evaporated in one process, and then the first light-emitting layer 23 of another color can be evaporated in another process.

In some examples, the plurality of second light-emitting layers 25 include a plurality of second blue light-emitting layers 25B, a plurality of second red light-emitting layers 25R, and a plurality of second green light-emitting layers 25G.

The first auxiliary layer 22 includes film layers stacked in sequence, and the number of the film layers being a; the second auxiliary layer 24 includes b film layers stacked in sequence; and the third auxiliary layer 26 includes c film layers stacked in sequence. a, b, c are all positive integers.

The optical thickness of the a film layers, the optical thickness of the b film layers and the optical thickness of the c film layers satisfy the formula:

$$0.7 \leq \frac{{\sum }_{i = 1}^{b} {r}_{i}}{{\sum }_{h = 1}^{a} {r}_{h} + {\sum }_{j = 1}^{c} {r}_{j}} \leq 1.3 , \vert \overline{n} {\sum }_{h = 1}^{a} {r}_{h} - \overline{n} {\sum }_{j = 1}^{c} {r}_{j} \vert \leq 30 nm .$$

n̅ is the average refractive index of the film layers between the anode layer and the cathode layer, and n̅ is in a range of 1.7 to 2.0; rₕ is the thickness of the h-th film layer in the a film layers, rᵢ is the thickness of the i-th film layer in the b film layers; and rⱼ is the thickness of the j-th film layer in the c film layers.

For example, a value of

$$\frac{{\sum }_{i = 1}^{b} {r}_{i}}{{\sum }_{h = 1}^{a} {r}_{h} + {\sum }_{j = 1}^{c} {r}_{j}}$$

may be, for example, 0.7, 0.83, 0.9, 1.1 or 1.3.

It should be noted that the average refractive index is a sum of optical thicknesses of the film layers located between the anode layer 21 and the cathode layer 27 divided by a sum of actual thicknesses of the film layers located between the anode layer 21 and the cathode layer 27. Alternatively, the average refractive index of the film layers between the anode layer 21 and the cathode layer 27 can be directly measured by a refractive index testing device (e.g., a refractometer or an ellipsometer).

For example, the value of n may be, for example, 1.7, 1.75, 1.8, 1.9 or 2.0.

In some examples, in the display substrate 100 provided in the above embodiments, a difference between refractive indexes of any two of the film layers located between the anode layer 21 and the cathode layer 27 is less than or equal to 0.32. With this setting, the refractive indexes of any two of the film layers located between the anode layer 21 and the cathode layer 27 may be made relatively close, so that the difference between the refractive indexes of any two of the film layers located between the anode layer 21 and the cathode layer 27 is relatively small. Thus, the sudden change in the refractive index of each film layer may be reduced, which makes the light-emitting device 2a has good light extraction efficiency and reduces the dispersion of the light emitted by the light-emitting device 2a.

It should be noted that the structure of the display substrate 100 in this embodiment is the same as that of the display substrate 100 in the above some embodiments. Optionally, the backplane 1 in this embodiment has the same features as the backplane 1 in the above some embodiments. The light-emitting device layer 2 in this embodiment has the same features as the light-emitting device layer 2 in the above some embodiments. For details, reference may be made to the above description, which will not be repeated here.

In some examples, in the display substrate 100 provided in the above embodiments, material types of the film layers between the anode layer 21 and the cathode layer 27 and refractive indexes of the film layers for blue light with a wavelength of 460 nm are shown in Table 10 below.

TABLE 10

| Film layer | Material | Refractive |
|---|---|---|
| name | type | index |
| Hole injection layer | Carbazole doped | 1.74 |
| | radialene | |
| First hole transport layer | Carbazole | 1.74 |
| Electron blocking layer | Carbazole | 1.87 |
| First hole blocking layer | Triazine | 1.88 |
| First electron transport layer | Triazine | 2.00 |
| First charge generation layer | Phosphorus oxide | 1.82 |
| Second charge generation layer | Carbazole | 1.74 |
| | doped radialene | |
| Second hole transport layer | Carbazole | 1.74 |
| Sub-microcavity | Carbazole | 1.87 |
| adjustment layer | | |
| of each color | | |
| Second hole blocking layer | Triazine | 1.86 |
| Second electron transport layer | Triazine | 1.79 |
| Electron injection layer | Metal complex | 1.68 |

It can be seen from Table 10 that the difference between the refractive indexes of any two of the film layers located between the anode layer 21 and the cathode layer 27 is less than or equal to 0.32, which means that the refractive indexes of any two of the film layers located between the anode layer 21 and the cathode layer 27 are relatively close. By selecting the material and refractive index of each film layer located between the anode layer 21 and the cathode layer 27, the difference between the refractive indexes of any two of the film layers located between the anode layer 21 and the cathode layer 27 may be further reduced, and the sudden change in the refractive index of each film layer may be further reduced. Thus, the light-emitting device 2a has good light extraction efficiency, and dispersion of the light emitted by the light-emitting device 2a is reduced.

The foregoing descriptions are merely specific embodiments of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display substrate, comprising:
a backplane;
an anode layer, a first auxiliary layer, a second auxiliary layer, a third auxiliary layer and a cathode layer that are stacked on the backplane in sequence, wherein microcavities are formed between the anode layer and the cathode layer;
a first light-emitting layer disposed between the first auxiliary layer and the second auxiliary layer; and
a plurality of second light-emitting layers of at least two different colors disposed between the second auxiliary layer and the third auxiliary layer, wherein
the first auxiliary layer includes film layers stacked in sequence, a number of the film layers being a; an optical thickness of the a film layers is L₁, and L₁ satisfies:
$${L}_{1} = {\sum }_{h = 1}^{a} {n}_{h} {r}_{h} ,$$
where a is a positive integer, nₕ is a refractive index of an h-th film layer in the a film layers, and rₕ is a thickness of the h-th film layer;
the second auxiliary layer includes b film layers stacked in sequence, an optical thickness of the b film layers is L₂, and L₂ satisfies:
$${L}_{2} = {\sum }_{i = 1}^{b} {n}_{i} {r}_{i} ,$$
where b is a positive integer, nᵢ is a refractive index of an i-th film layer in the b film layers, and rᵢ is a thickness of the i-th film layer;
the third auxiliary layer includes c film layers stacked in sequence, an optical thickness of the c film layers is L₃, and L₃ satisfies:
$${L}_{3} = {\sum }_{j = 1}^{c} {n}_{j} {r}_{j} ,$$
where c is a positive integer, nⱼ is a refractive index of a j-th film layer in the c film layers, and rⱼ is a thickness of the j-th film layer;
L₁, L₂ and L₃ satisfy a formula:
$$0.7 \leq \frac{{L}_{2}}{{L}_{1} + {L}_{3}} \leq 1.3 , \vert {L}_{1} - {L}_{3} \vert \leq 30 nm .$$

2. The display substrate according to claim 1, wherein
the plurality of second light-emitting layers include a plurality of second blue light-emitting layers, a plurality of second red light-emitting layers and a plurality of second green light-emitting layers; and
a wavelength of light emitted by the first light-emitting layer is less than a wavelength of light emitted by second light-emitting layers of at least one color.

3. The display substrate according to claim 2, wherein the first light-emitting layer includes a first guest material, a second light-emitting layer in the second light-emitting layers of at least one color includes a second guest material;
an emission spectrum of the first guest material at least partially overlaps with an absorption spectrum of the second guest material of the second light-emitting layers of at least one color.

4. The display substrate according to claim 3, wherein an overlapping range between the emission spectrum of the first guest material and the absorption spectrum of the second guest material is greater than or equal to 60% of a wavelength range of the emission spectrum of the first guest material; or
an overlapping range between the emission spectrum of the first guest material and the absorption spectrum of the second guest material is greater than or equal to 60% of a wavelength range of the absorption spectrum of the second guest material.

5. (canceled)

6. The display substrate according to claim 3, wherein a peak value of the emission spectrum of the first guest material is less than 600 nm; or
a peak value of the emission spectrum of the first guest material is in a range of 465 nm to 475 nm, and a peak value of an absorption spectrum of a second guest material of the second green light-emitting layers is in a range of 507 nm to 517 nm; or
a peak value of the emission spectrum of the first guest material is in a range of 525 nm to 535 nm, a peak value of an absorption spectrum of a second guest material of the second green light-emitting layers is in a range of 510 nm to 520 nm, and a peak value of an absorption spectrum of a second guest material of the second red light-emitting layers is in a range of 595 nm to 605 nm.

7. The display substrate according to claim 3, wherein the first guest material includes at least one luminescent material;
in a case where the first guest material includes two luminescent materials, a distance between peaks of emission spectrums of the two luminescent materials is less than or equal to 30 nm; and/or
in a case where the first guest material includes two luminescent materials, at least one of the two luminescent materials is doped with boron element, and a doping ratio of the boron element is in a range of 0.5% to 5%.

8-10. (canceled)

11. The display substrate according to claim 3, wherein the second guest material of the second light-emitting layers of at least one color includes at least one luminescent material;
in a case where the second guest material includes two luminescent materials, a distance between peaks of emission spectrums of the two luminescent materials is less than or equal to 30 nm; and/or
in a case where the second guest material includes two luminescent materials, at least one of the two luminescent materials is doped with boron element, and a doping ratio of the boron element is in a range of 0.5% to 5%.

12. (canceled)

13. The display substrate according to claim 11, wherein the first guest material includes at least one material of fluorescent materials, phosphorescent materials and a thermally activated delayed fluorescence material; and/or
the second guest material includes at least one material of fluorescent materials, phosphorescent materials, or a thermally activated delayed fluorescence material with a multiple resonance property.

14. The display substrate according to claim 3, wherein the first light-emitting layer further includes a first host material, and the first host material includes a single host material or a PN hybrid host material.

15. The display substrate according to claim 3, wherein a material of the second light-emitting layers of at least one color further includes a second host material, and the second host material includes a bipolar host material.

16. The display substrate according to claim 15, wherein the second host material includes a single host material or a PN hybrid host material;
in a case where the second host material is the PN hybrid host material, an N-type material in the PN hybrid host material has a thermally activated delayed fluorescence property.

17. The display substrate according to claim 2, wherein a microcavity in the microcavities includes a plurality of sub-microcavities, and the plurality of sub-microcavities include a red sub-microcavity corresponding to a second red light-emitting layer in the plurality of second red light-emitting layers, a green sub-microcavity corresponding to a second green light-emitting layer in the plurality of second green light-emitting layers, and a blue sub-microcavity corresponding to a second blue light-emitting layer in the plurality of second blue light-emitting layers;
a number of film layers that are located between the anode layer and the cathode layer and correspond to a sub-microcavity of any color is d; and an optical thickness of the d film layers is L, and L satisfies:
$$L = {\sum }_{m = 1}^{d} {n}_{m} {r}_{m} , 2 L + \frac{φ}{2 π} = k λ ,$$
where d is a positive integer, nₘ is a refractive index of an m-th film layer in the d film layers, rₘ is a thickness of the m-th film layer, k is a natural number, λ is a peak wavelength of a target spectrum, and φ is a phase shift caused after target light is reflected by the anode layer.

18. The display substrate according to claim 17, wherein
a length of the blue sub-microcavity is less than a length of the red sub-microcavity; and
the length of the blue sub-microcavity is less than a length of the green sub-microcavity.

19. The display substrate according to claim 1, a thickness of the first light-emitting layer is in a range of 15 nm to 60 nm; and/or
a thickness of a second light-emitting layer in the plurality of second light-emitting layers of at least two different colors is in a range of 10 nm to 50 nm.

20. The display substrate according to claim 2, wherein the first auxiliary layer includes a light-transmitting conductive layer, a hole injection layer, a first hole transport layer and an electron blocking layer; and/or
the second auxiliary layer includes a first hole blocking layer, a first electron transport layer, a first charge generation layer, a second charge generation layer and a microcavity adjustment layer; and/or
the third auxiliary layer includes a second hole blocking layer, a second electron transport layer and an electron injection layer.

21. The display substrate according to claim 20, wherein the microcavity adjustment layer includes:
a second hole transport layer;
a red sub-microcavity adjustment layer disposed between the second hole transport layer and a second red light-emitting layer in the plurality of second red light-emitting layers;
a green sub-microcavity adjustment layer disposed between the second hole transport layer and a second green light-emitting layer in the plurality of second green light-emitting layers; and
a blue sub-microcavity adjustment layer disposed between the second hole transport layer and a second blue light-emitting layer inn the plurality of second blue light-emitting layers;
wherein lengths of the red sub-microcavity adjustment layer and the blue sub-microcavity adjustment layer are different, and lengths of the green sub-microcavity adjustment layer and the blue sub-microcavity adjustment layer are different.

22. The display substrate according to claim 21, wherein the red sub-microcavity adjustment layer includes a red hole transport layer and a red electron blocking layer that are stacked in sequence in a direction away from the backplane; and the green sub-microcavity adjustment layer includes a green hole transport layer and a green electron blocking layer that are stacked in sequence in the direction away from the backplane;
wherein the red hole transport layer and the green hole transport layer are used to adjust lengths of respective color sub-microcavities.

23. (canceled)

24. (canceled)

25. A display substrate, comprising:
a backplane;
an anode layer, a first auxiliary layer, a second auxiliary layer, a third auxiliary layer and a cathode layer that are stacked on the backplane in sequence; microcavities are formed between the anode layer and the cathode layer;
a first light-emitting layer disposed between the first auxiliary layer and the second auxiliary layer; and
a plurality of second light-emitting layers of at least two different colors disposed between the second auxiliary layer and the third auxiliary layer, wherein
the first auxiliary layer includes film layers stacked in sequence, a number of the film layers being a; the second auxiliary layer includes b film layers stacked in sequence; and the third auxiliary layer includes c film layers stacked in sequence; a, b, c are all positive integers;
an optical thickness of the a film layers, an optical thickness of the b film layers and an optical thickness of the c film layers satisfy a formula:
$$0.7 \leq \frac{{\sum }_{i = 1}^{b} {r}_{i}}{{\sum }_{h = 1}^{a} {r}_{h} + {\sum }_{j = 1}^{c} {r}_{j}} \leq 1.3 , \vert \overline{n} {\sum }_{h = 1}^{a} {r}_{h} - \overline{n} {\sum }_{j = 1}^{c} {r}_{j} \vert \leq 30 nm ,$$
where n̅ is an average refractive index of film layers between the anode layer and the cathode layer, and n̅ is in a range of 1.7 to 2.0;
rₕ is a thickness of an h-th film layer in the a film layers; rᵢ is a thickness of an i-th film layer in the b film layers; and rⱼ is a thickness of a j-th film layer in the c film layers.

26. A display substrate, comprising:
a backplane;
an anode layer, a first auxiliary layer, a second auxiliary layer, a third auxiliary layer and a cathode layer that are stacked on the backplane in sequence, wherein the second auxiliary layer includes a charge generation layer, and microcavities are formed between the anode layer and the cathode layer;
a first light-emitting layer disposed between the first auxiliary layer and the second auxiliary layer, and capable of emitting light of at least two different colors; and
a plurality of second light-emitting layers disposed between the second auxiliary layer and the third auxiliary layer, the plurality of second light-emitting layers including a plurality of second blue light-emitting layers, a plurality of second red light-emitting layers and a plurality of second green light-emitting layers, wherein
the first auxiliary layer includes film layers stacked in sequence, a number of the film layers being a; the second auxiliary layer includes b film layers stacked in sequence; and the third auxiliary layer includes c film layers stacked in sequence; a, b, c are all positive integers;
an optical thickness of the a film layers, an optical thickness of the b film layers and an optical thickness of the c film layers satisfy a formula:
$$0.7 \leq \frac{{\sum }_{i = 1}^{b} {r}_{i}}{{\sum }_{h = 1}^{a} {r}_{h} + {\sum }_{j = 1}^{c} {r}_{j}} \leq 1.3 , \vert \overline{n} {\sum }_{h = 1}^{a} {r}_{h} - \overline{n} {\sum }_{j = 1}^{c} {r}_{j} \vert \leq 30 nm ,$$
where n̅ is an average refractive index of film layers between the anode layer and the cathode layer, and n̅ is in a range of 1.7 to 2.0;
rₕ is a thickness of an h-th film layer in the a film layers, rᵢ is a thickness of an i-th film layer in the b film layers, and rⱼ is a thickness of a j-th film layer in the c film layers.

27. A display apparatus, comprising the display substrate according to claim 1.
